(19) United States
(12) Patent Application Publication
(10) Pub. No.: US 2025/0351446 A1
(43) Pub. Date: Nov. 13, 2025

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Ta-Chun LIN, Hsinchu (TW); Jhon-Jhy LIAW, Zhudong Township (TW)

(21) Appl. No.: 18/662,185

(22) Filed: May 13, 2024

(51) Int. Cl. H01L 29/423; H01L 21/8234; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/115; H10D 62/121; H10D 62/151; H10D 64/017; H10D 64/021; H10D 84/0135; H10D 84/0151; H10D 84/038; H10D 84/83

(57) ABSTRACT

Semiconductor structures and methods for manufacturing the same are provided. The semiconductor structure includes first nanostructures formed over a substrate along a first direction, and second nanostructures parallel to the first nanostructures. The semiconductor structure includes a merged S/D structure formed on the first nanostructures and the second nanostructures, and a first gate structure formed over the first nanostructures and the second nanostructures along a second direction. The semiconductor structure includes a second gate structure formed parallel to the first gate structure. The semiconductor structure includes a first dielectric wall structure formed along the first direction. The first gate structure and the merged S/D structure are divided by the first dielectric wall structure, and an end of the first dielectric wall structure extends beyond an outer sidewall surface of the merged S/D structure.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A to 1E illustrate perspective views of intermediate stages of manufacturing a semiconductor structure in accordance with some embodiments.

FIG. 2 shows a top-view representation of the semiconductor structure, in accordance with some embodiments.

FIGS. 3A-1 to 3L-1 illustrate cross-sectional representations of various stages of manufacturing the semiconductor structure shown along line A-A′ in FIG. 1E and in FIG. 2, in accordance with some embodiments.

FIGS. 3A-2 to 3L-2 illustrate cross-sectional representations of various stages of manufacturing the semiconductor structure shown along line B-B′ in FIG. 1E and in FIG. 2, in accordance with some embodiments.

FIGS. 3A-3 to 3L-3 illustrate cross-sectional representations of various stages of manufacturing the semiconductor structure shown along line C-C′ in FIG. 1E and in FIG. 2, in accordance with some embodiments.

FIG. 3L′-1 illustrates a cross-sectional representation of a semiconductor structure, in accordance with some embodiments.

FIG. 4 shows a top-view representation of the semiconductor structure after forming the first gate structure and the second gate structure, in accordance with some embodiments.

FIG. 5 illustrates a cross-sectional representation of the semiconductor structure shown along line D-D′ in FIG. 4, in accordance with some embodiments.

FIG. 6 shows a top-view representation of a semiconductor structure, in accordance with some embodiments.

FIG. 7 illustrates a cross-sectional representation of the semiconductor structure shown along line A-A′ in FIG. 6, in accordance with some embodiments.

FIG. 8 illustrates a cross-sectional representation of the semiconductor structure shown along line B-B′ in FIG. 6, in accordance with some embodiments.

FIGS. 9A-1 to 9E-1 illustrate cross-sectional representations of various stages of manufacturing a semiconductor structure shown along line A-A′ in FIG. 1E and in FIG. 2, in accordance with some embodiments.

FIGS. 9A-2 to 9E-2 illustrate cross-sectional representations of various stages of manufacturing the semiconductor structure shown along line B-B′ in FIG. 1E and in FIG. 2, in accordance with some embodiments.

FIGS. 9A-3 to 9E-3 illustrate cross-sectional representations of various stages of manufacturing the semiconductor structure shown along line C-C′ in FIG. 1E and in FIG. 2, in accordance with some embodiments.

FIG. 10 shows a top-view representation of the semiconductor structure after forming the first dielectric wall structure, in accordance with some embodiments.

FIG. 11 shows a top-view representation of a semiconductor structure, in accordance with some embodiments.

FIG. 12 shows a top-view representation of a semiconductor structure, in accordance with some embodiments.

FIG. 13 shows a top-view representation of a semiconductor structure, in accordance with some embodiments.

FIG. 14 illustrates a cross-sectional representation of the semiconductor structure shown along line A-A′ in FIG. 13, in accordance with some embodiments.

FIG. 15 illustrates a cross-sectional representation of the semiconductor structure shown along line B-B′ in FIG. 13, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of semiconductor structures and methods for forming the same are provided. The semiconductor structure includes first nanostructures and second nanostructures along a first direction (e.g. x-axis). A first gate structure is formed over the first nanostructures and the second nanostructures along the second direction (e.g. y-direction). A first S/D structure is formed over the first nanostructures, and a second S/D structure is formed over the second nanostructures. A first gate spacer layer is formed on the sidewall surface of the first gate structure, and a second gate structure is formed parallel to the first gate structure. A second gate spacer layer is formed on the sidewall surface of the second gate structure. A first dielectric wall structure is formed along the first direction, and the first dielectric wall structure is between the first S/D structure and the second S/D structure. One end of the first dielectric wall structure extends beyond the sidewall surface of the second gate spacer layer.

In some embodiments, the first S/D structure and the second S/D structure are merged to form a merged S/D structure. The first dielectric wall structure is configured to divide or separate the merged S/D structure. One end of the first dielectric wall structure extends beyond the outer sidewall surface of the merged S/D structure to make sure the merged S/D structure is completely divided. Thus, any unwanted connection between the two adjacent S/D structures can be prevented. Therefore, the leakage of the semiconductor structures is reduced, and the performances and the yield of the semiconductor structures are improved. The source/drain (S/D) structure or region(s) may refer to a source or a drain, individually or collectively dependent upon the context.

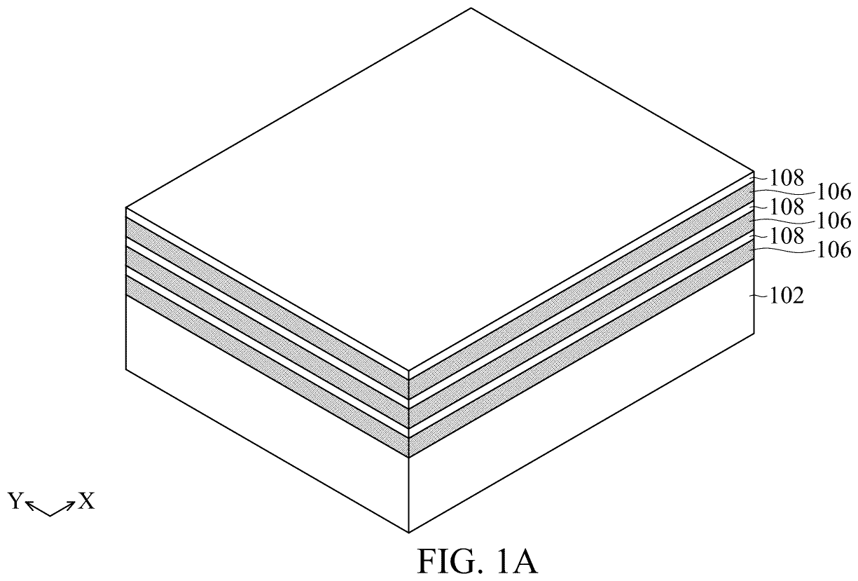

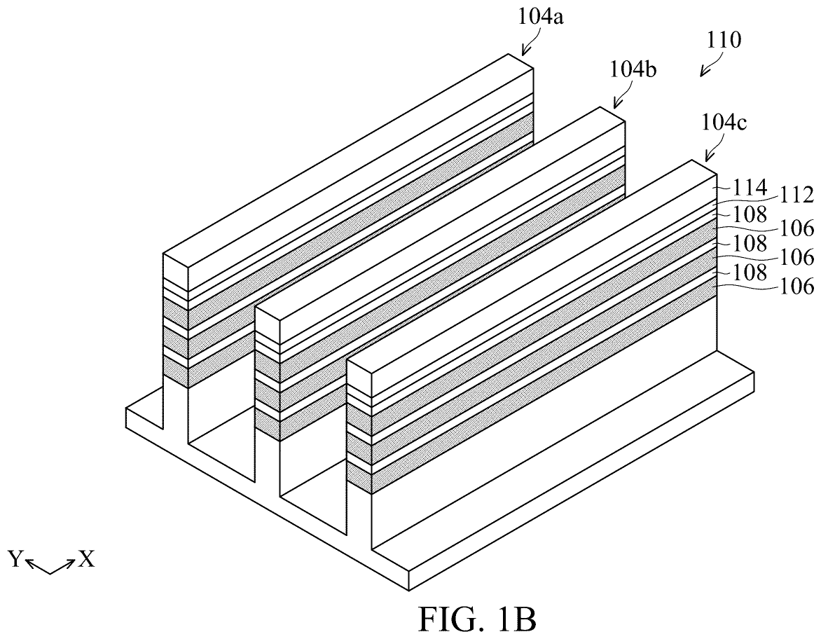

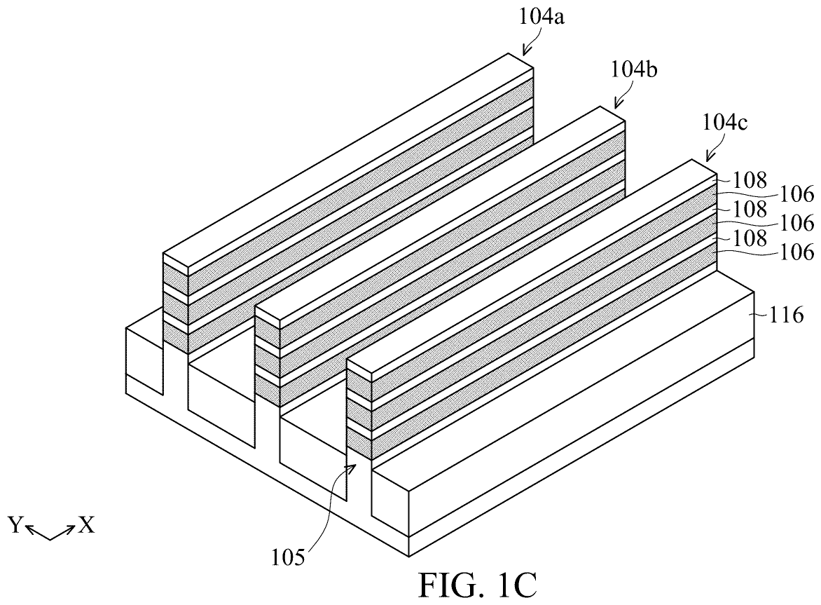

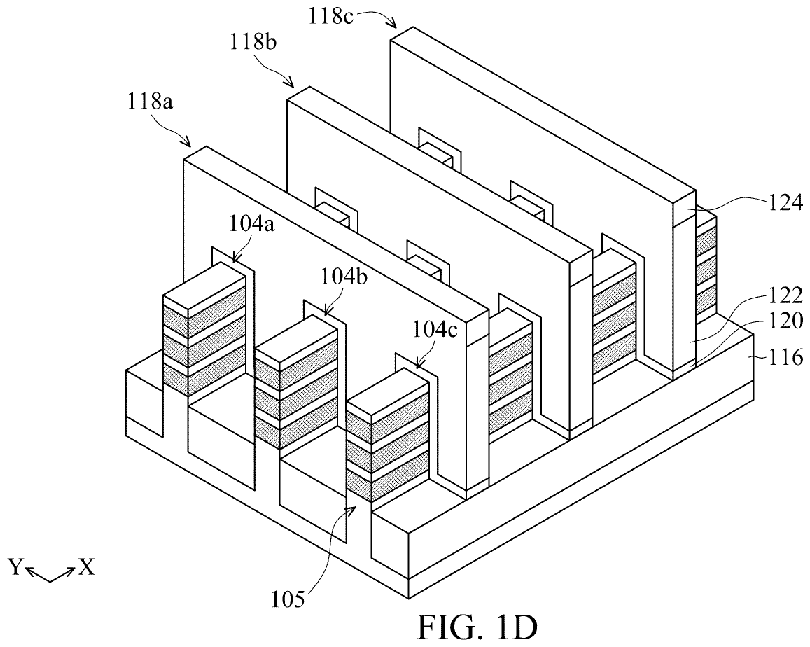

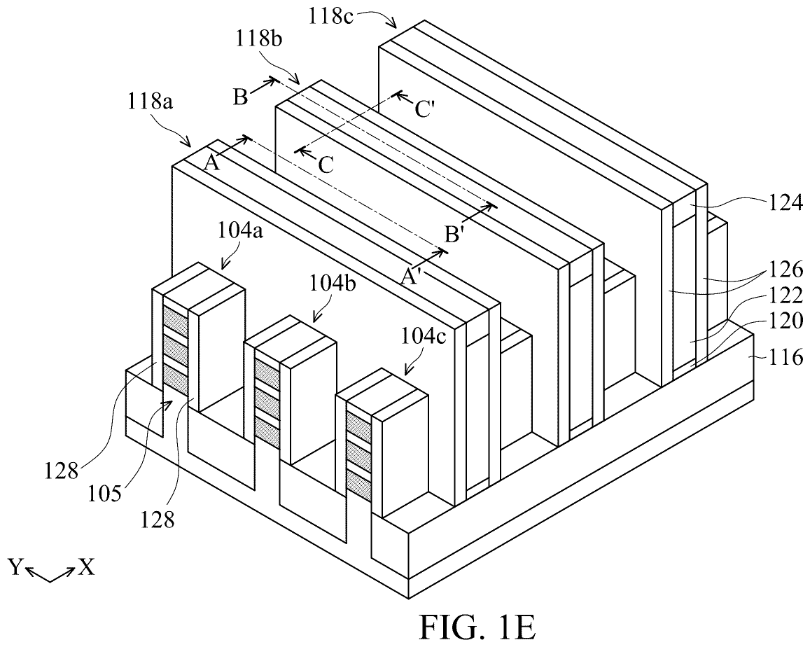

FIGS. 1A to 1E illustrate perspective views of intermediate stages of manufacturing a semiconductor structure 100a, in accordance with some embodiments. As shown in FIG. 1A, first semiconductor material layers 106 and second semiconductor material layers 108 are formed over a substrate 102.

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although three first semiconductor material layers 106 and three second semiconductor material layers 108 are formed, the semiconductor structure may include more or fewer first semiconductor material layers 106 and second semiconductor material layers 108. For example, the semiconductor structure may include two to five of the first semiconductor material layers 106 and the second semiconductor material layers.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

Afterwards, as shown in FIG. 1B, after the first semiconductor material layers 106 and the second semiconductor material layers 108 are formed as a semiconductor material stack over the substrate 102, the semiconductor material stack is patterned to form a first fin structure 104a, a second fin structure 104b and a third fin structure 104c, in accordance with some embodiments. In some embodiments, each of the first fin structure 104a, the second fin structure 104b and the third fin structure 104c includes a base fin structure 105 and the semiconductor material stack of the first semiconductor material layers 106 and the second semiconductor material layers 108.

In some embodiments, the patterning process includes forming a mask structure 110 over the semiconductor material stack, and etching the semiconductor material stack and the underlying substrate 102 through the mask structure 110. In some embodiments, the mask structure 110 is a multilayer structure including a pad oxide layer 112 and a nitride layer 114 formed over the pad oxide layer 112. The pad oxide layer 112 may be made of silicon oxide, which is formed by thermal oxidation or chemical vapor deposition (CVD), and the nitride layer 114 may be made of silicon nitride, which is formed by chemical vapor deposition (CVD), such as low-temperature chemical vapor deposition (LPCVD) or plasma-enhanced CVD (PECVD).

Next, as shown in FIG. 1C, after the first fin structure 104a, the second fin structure 104b and the third fin structure 104c are formed, an isolation structure 116 is formed around first fin structure 104a and the second fin structure 104b and the third fin structure 104c, and the mask structure 110 is removed, in accordance with some embodiments. The isolation structure 116 is configured to electrically isolate active regions (e.g. the first fin structure 104a, the second fin structure 104b and the third fin structure 104c) of the semiconductor structure 100a and is also referred to as shallow trench isolation (STI) feature in accordance with some embodiments.

The isolation structure 116 may be formed by depositing an insulating layer over the substrate 102 and recessing the insulating layer so that the first fin structure 104a and the second fin structure 104b is protruded from the isolation structure 116. In some embodiments, the isolation structure 116 is made of silicon oxide, silicon nitride, silicon oxynitride (SiON), another suitable insulating material, or a combination thereof. In some embodiments, a dielectric liner (not shown) is formed before the isolation structure 116 is formed, and the dielectric liner is made of silicon nitride and the isolation structure formed over the dielectric liner is made of silicon oxide.

Afterwards, as shown in FIG. 1D, after the isolation structure 116 is formed, a first dummy gate structure 118a, a second dummy gate structure 118b and a third dummy gate structure 118c are formed across the first fin structure 104a, the second fin structure 104b and the third fin structure 104c and extend over the isolation structure 116, in accordance with some embodiments. The first dummy gate structure 118a, the second dummy gate structure 118b and the third dummy gate structure 118c may be used to define the source/drain (S/D) regions and the channel regions of the resulting semiconductor structure 100a.

In some embodiments, each of the first dummy gate structure 118a, each of the second dummy gate structure 118b and each of the third dummy gate structure 118c includes dummy gate dielectric layers 120 and dummy gate electrode layers 122. In some embodiments, the dummy gate dielectric layers 120 are made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layers 120 are formed using thermal oxidation, chemical vapor deposition (CVD), atomic vapor deposition (ALD), physical vapor deposition (PVD), another suitable method, or a combination thereof.

In some embodiments, the conductive material includes polycrystalline-silicon (poly-Si), poly-crystalline silicon-germanium (poly-SiGe), metallic nitrides, metallic silicides, metals, or a combination thereof. In some embodiments, the dummy gate electrode layers 122 are formed using chemical vapor deposition (CVD), physical vapor deposition (PVD), or a combination thereof.

In some embodiments, the hard mask layers 124 are formed over the first dummy gate structure 118a and the second dummy gate structure 118b. In some embodiments, the hard mask layers 124 include multiple layers, such as an oxide layer and a nitride layer. In some embodiments, the oxide layer is silicon oxide, and the nitride layer is silicon nitride.

The formation of the first dummy gate structure 118a, the second dummy gate structure 118b and the third dummy gate structure 118 may include conformally forming a dielectric material as the dummy gate dielectric layers 120. Afterwards, a conductive material may be formed over the dielectric material as the dummy gate electrode layers 122, and the hard mask layer 124 may be formed over the conductive material. Next, the dielectric material and the conductive material may be patterned through the hard mask layer 124 to form the dummy gate structure 118.

Next, as shown in FIG. 1E, after the first dummy gate structure 118a, the second dummy gate structure 118b and the third dummy gate structure 118c are formed, gate spacer layers 126 are formed along and covering opposite sidewalls of the first dummy gate structure 118a, the second dummy gate structure 118b and the third dummy gate structure 118c and fin spacer layers 128 are formed along and covering opposite sidewalls of the source/drain regions of the first fin structure 104a, the second fin structure 104b and the third fin structure 104c, in accordance with some embodiments.

The gate spacer layers 126 may be configured to separate source/drain (S/D) structures from the first dummy gate structure 118a, the second dummy gate structure 118b and the third dummy gate structure 118c and support the first dummy gate structure 118a, the second dummy gate structure 118b and the third dummy gate structure 118c, and the fin space layers 128 may be configured to constrain a lateral growth of subsequently formed source/drain structure and support the first fin structure 104a and the second fin structure 104b and the third fin structure 104c.

In some embodiments, the gate spacer layers 126 and the fin spacer layers 128 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. The formation of the gate spacer layers 126 and the fin spacer layers 128 may include conformally depositing a dielectric material covering the first dummy gate structure 118a, the second dummy gate structure 118b, the third dummy gate structure 118c, the first fin structure 104a, the second fin structure 104b and the isolation structure 116 over the substrate 102, and performing an anisotropic etching process, such as dry plasma etching, to remove the dielectric layer covering the top surfaces of the first dummy gate structure 118a, the second dummy gate structure 118b, the first fin structure 104a, the second fin structure 104b, and portions of the isolation structure 116.

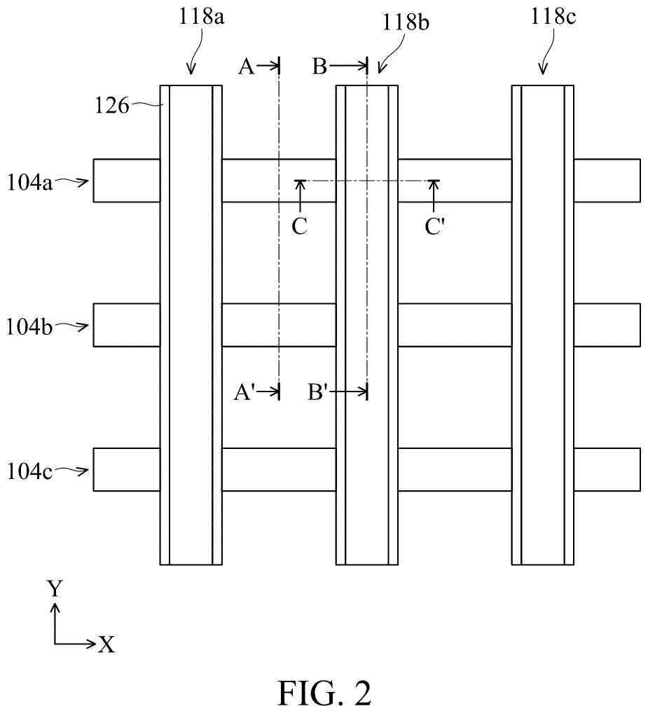

FIG. 2 shows a top-view representation of the semiconductor structure 100a, in accordance with some embodiments.

As shown in FIG. 2, the first fin structure 104a, the second fin structure 104b and the third fin structure 104c are formed along the first direction (e.g. X-axis). The first dummy gate structure 118a, the second dummy gate structure 118b and the third dummy gate structure 118c are formed along the second direction (e.g. Y-axis). The first dummy gate structure 118a, the second dummy gate structure 118b and third dummy gate structure 118c are formed across the first fin structure 104a, the second fin structure 104b and the third fin structure 104c. The gate spacer layers 126 are formed on sidewall surfaces of the first dummy gate structure 118a, the second dummy gate structure 118b and the third dummy gate structure 118c.

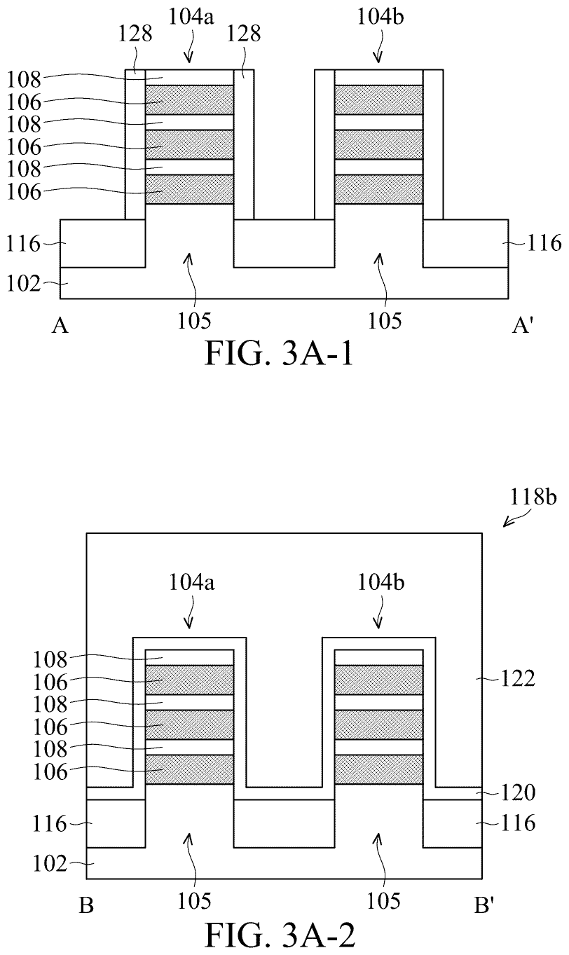

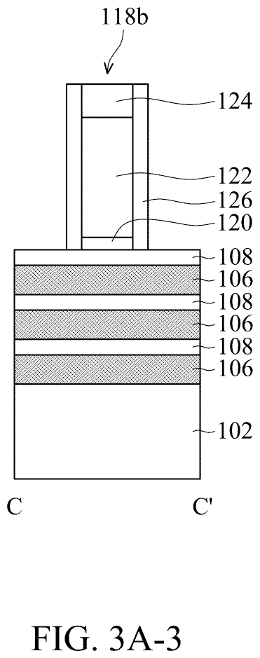

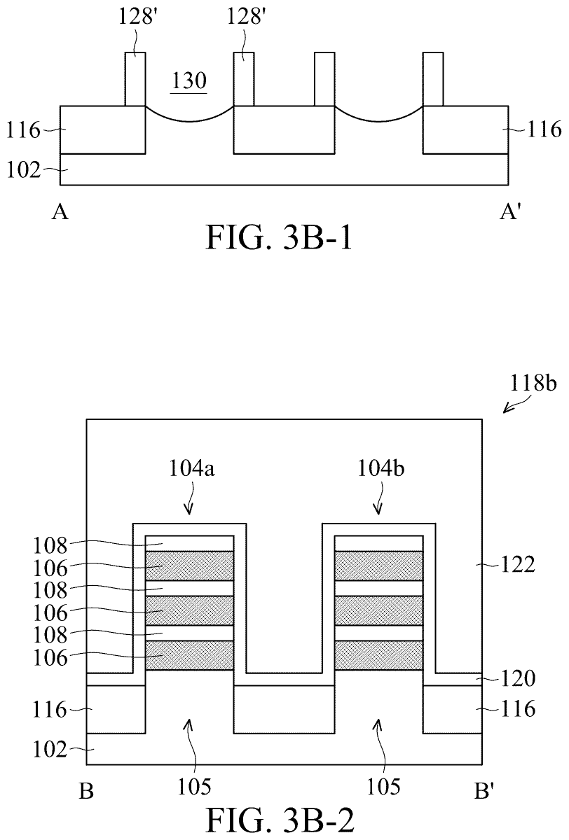

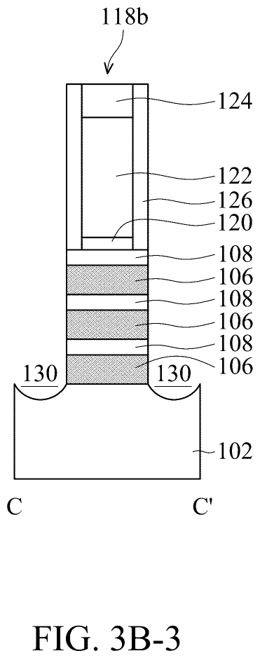

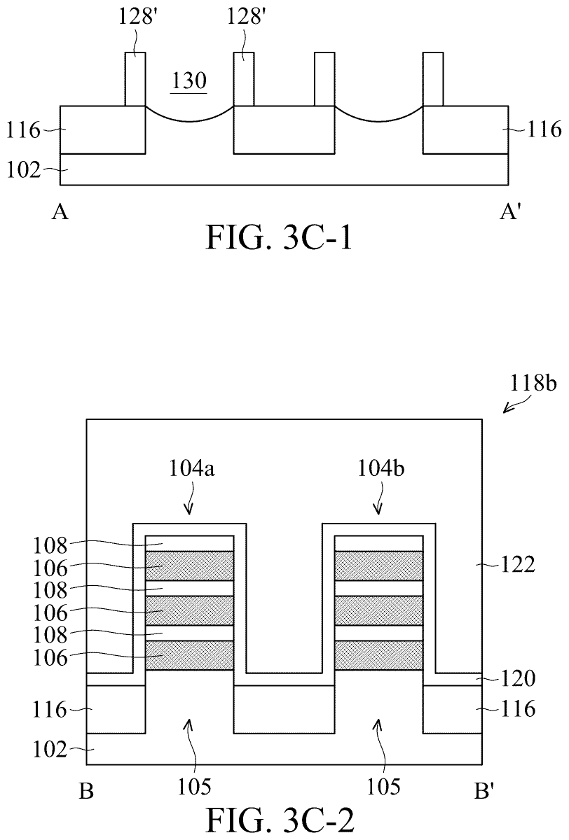

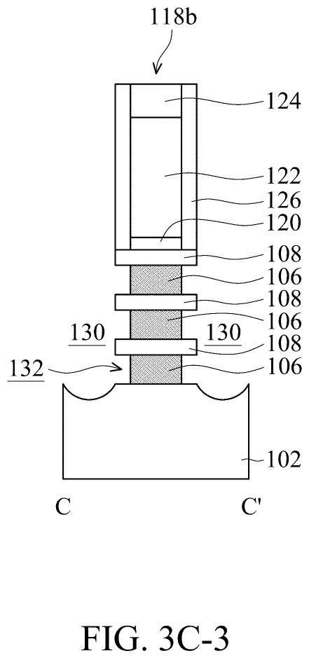

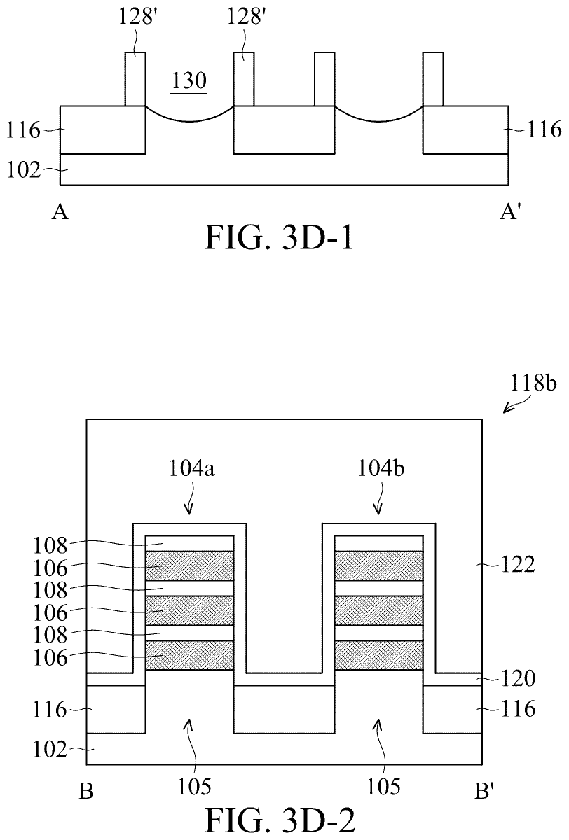

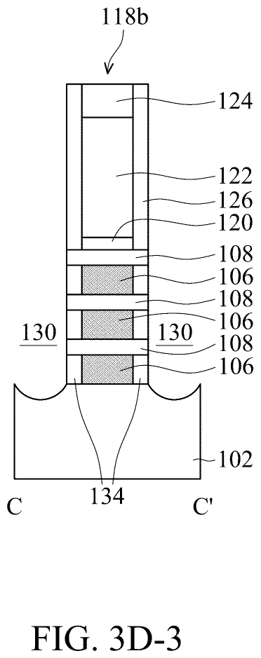

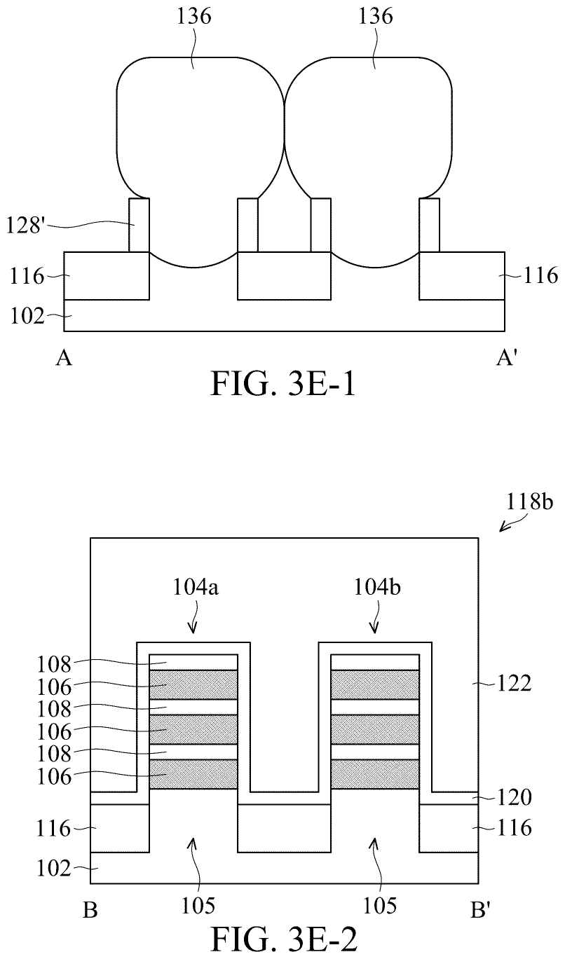

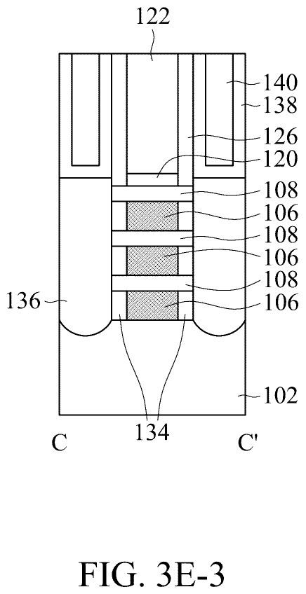

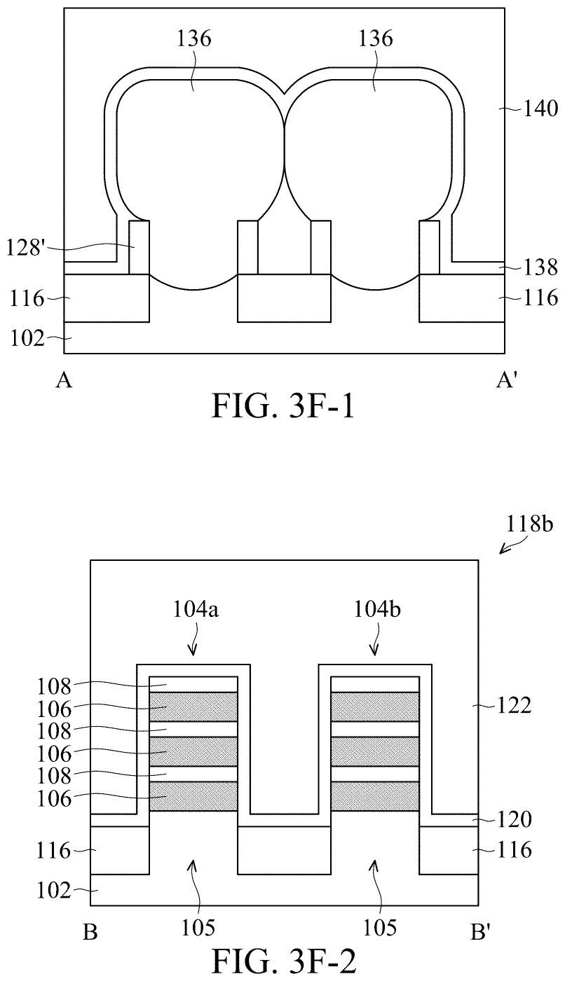

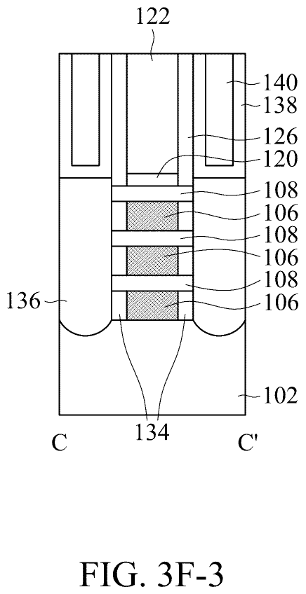

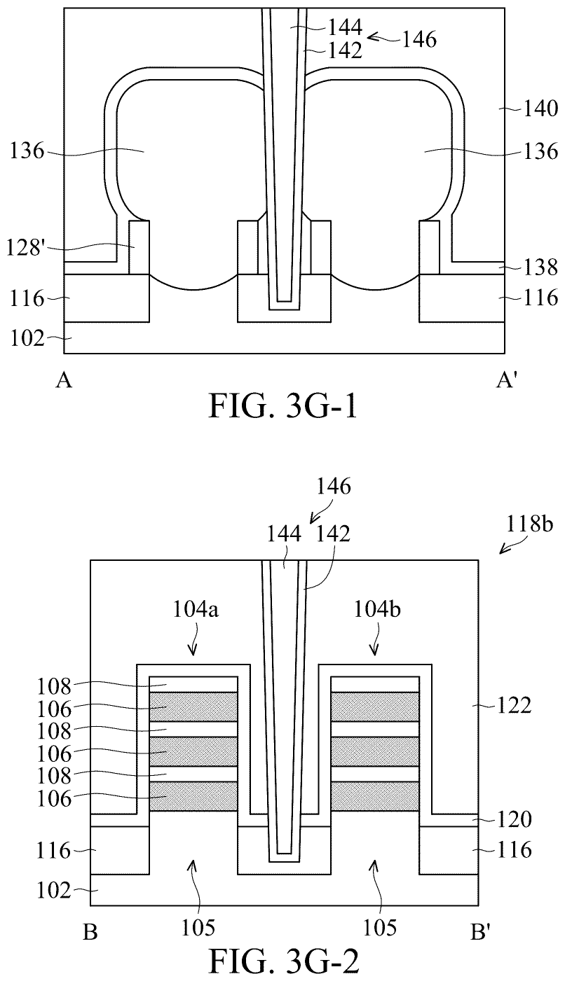

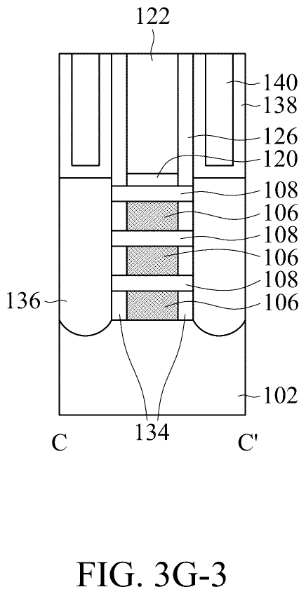

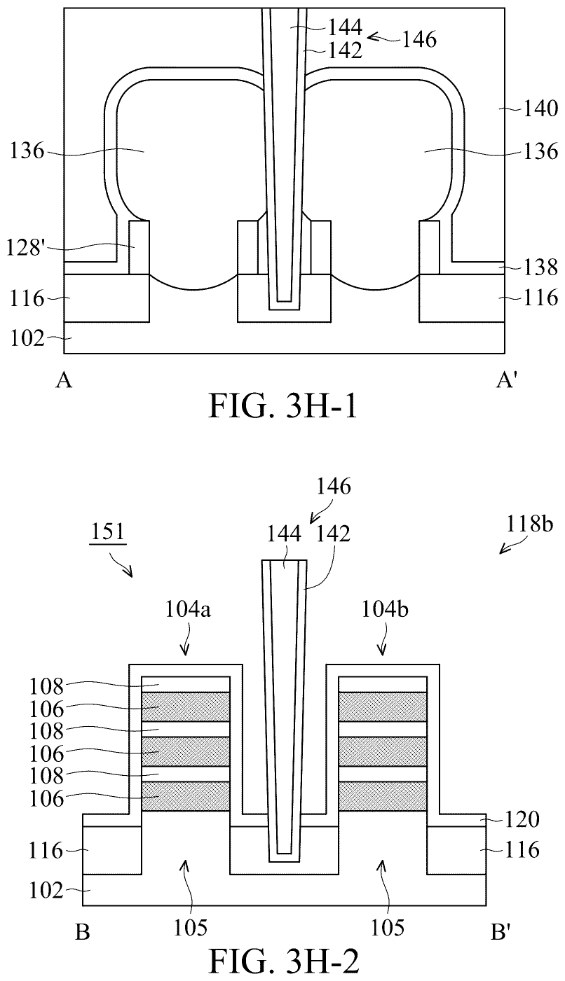

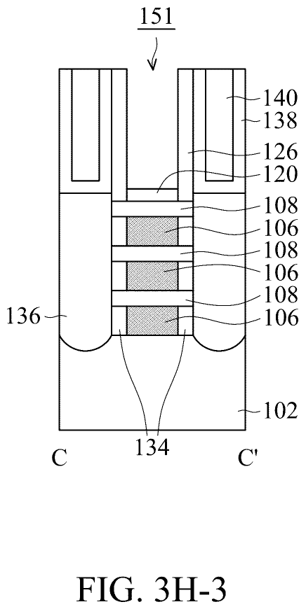

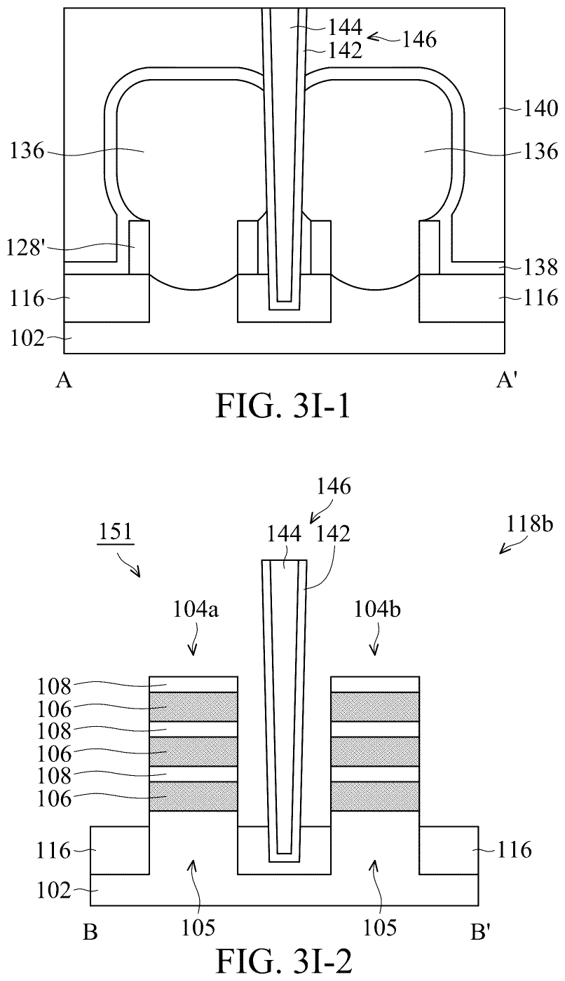

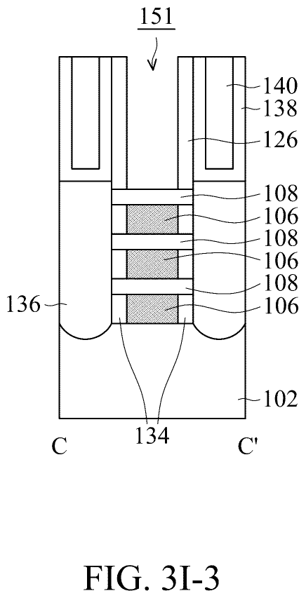

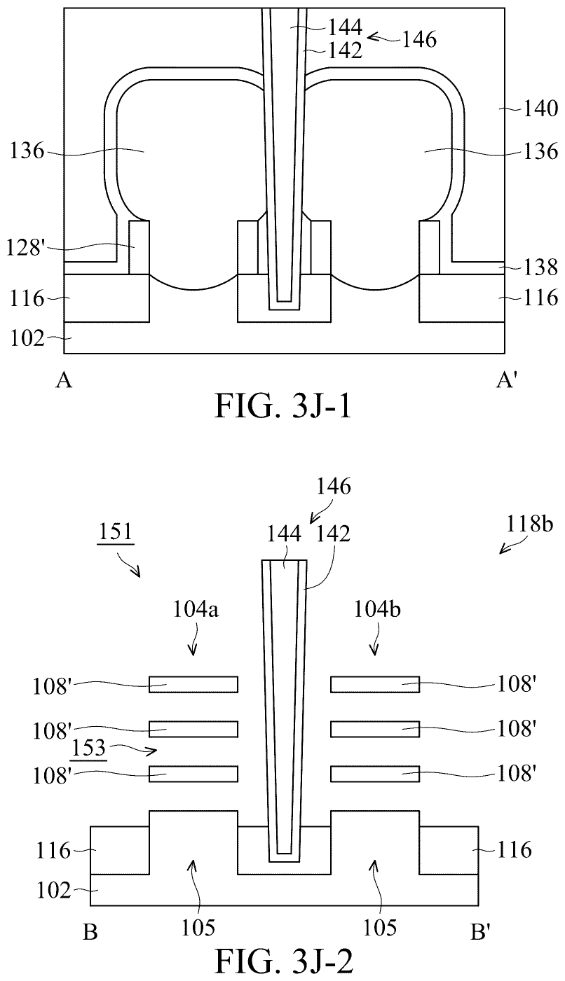

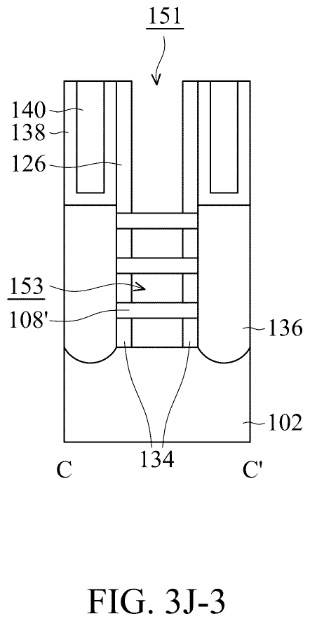

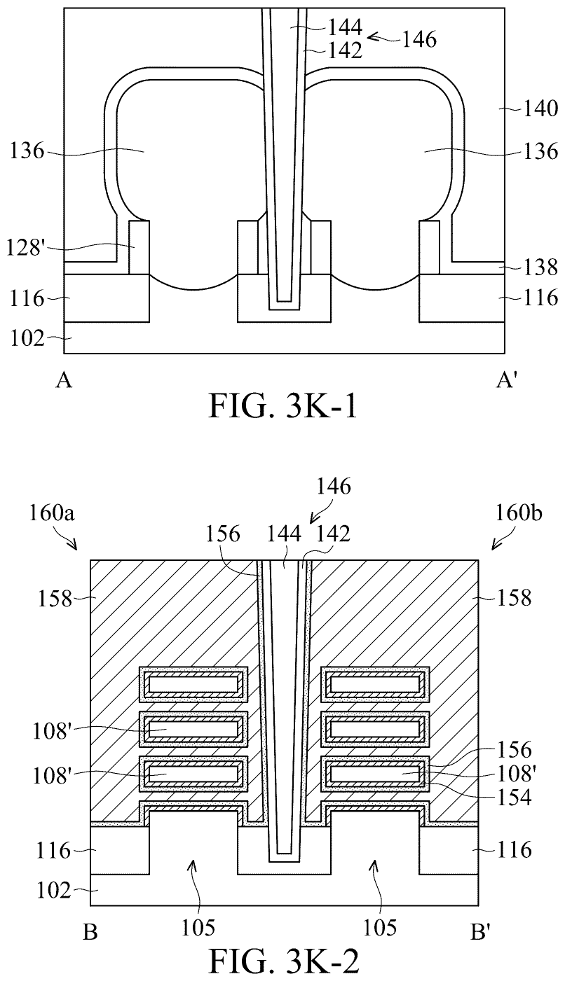

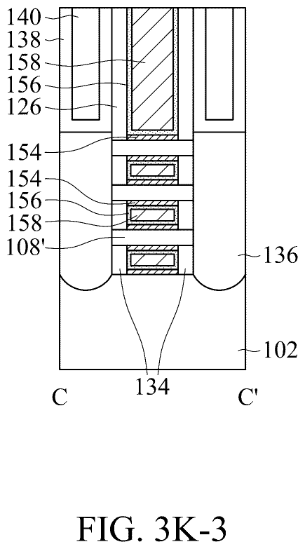

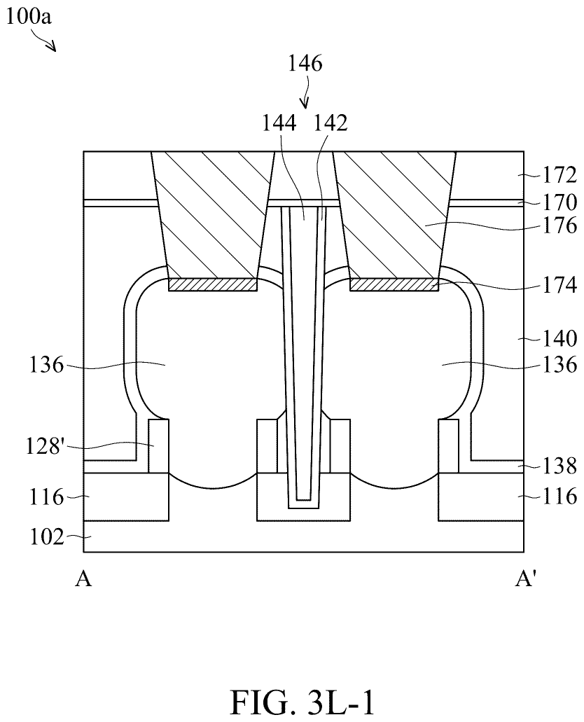

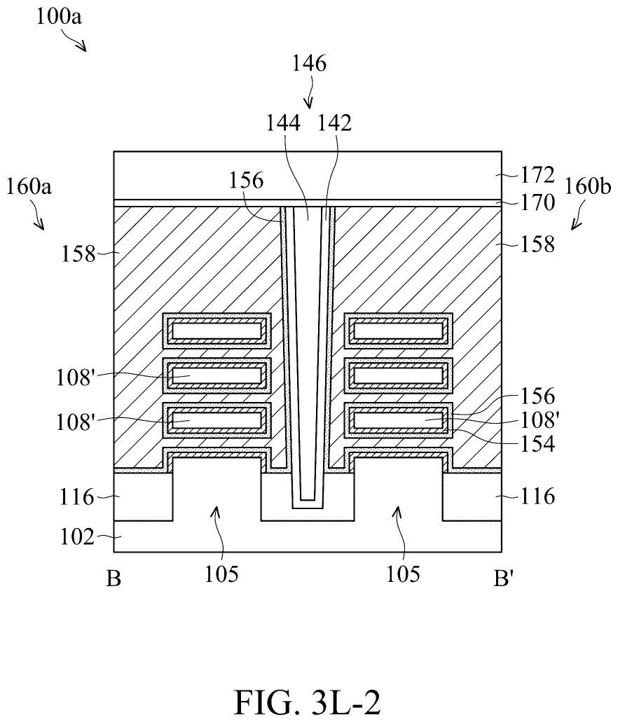

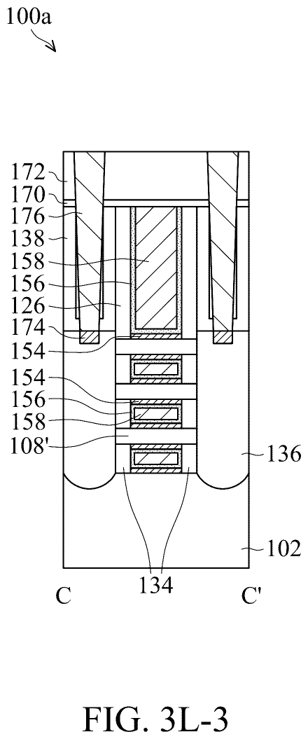

FIGS. 3A-1 to 3L-1 illustrate cross-sectional representations of various stages of manufacturing the semiconductor structure 100a shown along line A-A′ in FIG. 1E and in FIG. 2, in accordance with some embodiments. FIGS. 3A-2 to 3L-2 illustrate cross-sectional representations of various stages of manufacturing the semiconductor structure 100a shown along line B-B′ in FIG. 1E and in FIG. 2, in accordance with some embodiments. FIGS. 3A-3 to 3L-3 illustrate cross-sectional representations of various stages of manufacturing the semiconductor structure 100a shown along line C-C′ in FIG. 1E and in FIG. 2, in accordance with some embodiments.

More specifically, FIG. 3A-1 illustrates the cross-sectional representation shown along line A-A′ in FIG. 1E and FIG. 2. FIG. 3A-2 illustrates the cross-sectional representation shown along line B-B′ in FIG. 1E and FIG. 2 in accordance with some embodiments. FIG. 3A-3 illustrates the cross-sectional representation shown along line C-C′ in FIG. 1E and in FIG. 2.

Next, as shown in FIGS. 3B-1, 3B-2 and 3B-3, after the gate spacer layers 126 and the fin spacer layers 128 are formed, the source/drain (S/D) regions of the fin structure 104 are recessed to form source/drain (S/D) recesses 130, as shown in in accordance with some embodiments. More specifically, the first semiconductor material layers 106 and the second semiconductor material layers 108 not covered by first dummy gate structure 118a, the second dummy gate structure 118b and the gate spacer layers 126 are removed, in accordance with some embodiments. In addition, some portions of the base fin structure 105 are also recessed to form curved top surfaces, as shown in FIG. 3B-1 in accordance with some embodiments.

In some embodiments, the first fin structure 104a, the second fin structure 104b and the third fin structure 104c are recessed by performing an etching process. The etching process may be an anisotropic etching process, such as dry plasma etching, and the first dummy gate structure 118a, the second dummy gate structure 118b, the third dummy gate structure 118c and the gate spacer layers 126 are used as etching masks during the etching process. In some embodiments, the fin spacer layers 128 are also recessed to form lowered fin spacer layers 128′.

Afterwards, as shown in FIGS. 3C-1, 3C-2 and 3C-3, after the source/drain (S/D) recesses 130 are formed, the first semiconductor material layers 106 exposed by the source/drain recesses 130 are laterally recessed to form notches 132, in accordance with some embodiments.

In some embodiments, an etching process is performed on the semiconductor structure 100a to laterally recess the first semiconductor material layers 106 of the fin structure 104 from the source/drain recesses 130. In some embodiments, during the etching process, the first semiconductor material layers 106 have a greater etching rate (or etching amount) than the second semiconductor material layers 108, thereby forming notches 132 between adjacent second semiconductor material layers 108. In some embodiments, the etching process is an isotropic etching such as dry chemical etching, remote plasma etching, wet chemical etching, another suitable technique, and/or a combination thereof.

Next, as shown in FIGS. 3D-1, 3D-2 and 3D-3, inner spacer layers 134 are formed in the notches 132 between the second semiconductor material layers 108, in accordance with some embodiments. The inner spacer layers 134 are configured to separate the source/drain (S/D) structures and the gate structures formed in subsequent manufacturing processes in accordance with some embodiments. In some embodiments, the inner spacer layers 134 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the inner spacer layers 134 are formed by a deposition process, such as chemical vapor deposition (CVD) process, atomic layer deposition (ALD) process, another applicable process, or a combination thereof.

Afterwards, as shown in FIGS. 3E-1, 3E-2 and 3E-3, after the inner spacer layers 134 are formed, source/drain (S/D) structure 136 are formed in the S/D recesses 130, in accordance with some embodiments. In some embodiments, the two adjacent S/D structures 136 are connected to each other or merged to form a merged S/D structure 136. In some other embodiments, the two adjacent S/D structures 136 are not merged.

In some embodiments, the source/drain (S/D) structures 136 are formed using an epitaxial growth process, such as Molecular beam epitaxy (MBE), Metal-organic Chemical Vapor Deposition (MOCVD), Vapor-Phase Epitaxy (VPE), another applicable epitaxial growth process, or a combination thereof. In some embodiments, the source/drain (S/D) structures 136 are made of any applicable material, such as Ge, Si, GaAs, AlGaAs, SiGe, GaAsP, SiP, SiC, SiCP, or a combination thereof.

In some embodiments, the source/drain (S/D) structures 136 are in-situ doped during the epitaxial growth process. For example, the source/drain (S/D) structure 136 may be the epitaxially grown SiGe doped with boron (B). For example, the source/drain (S/D) structure 136 may be the epitaxially grown Si doped with carbon to form silicon: carbon (Si:C) source/drain features, phosphorous to form silicon: phosphor (Si:P) source/drain features, or both carbon and phosphorous to form silicon carbon phosphor (SiCP) source/drain features. In some embodiments, the source/drain (S/D) structure 136 is doped in one or more implantation processes after the epitaxial growth process

Afterwards, as shown in FIGS. 3F-1, 3F-2 and 3F-3, a contact etch stop layer (CESL) 138 is conformally formed to cover the S/D structures 136, and an interlayer dielectric (ILD) layer 140 is formed over the contact etch stop layers 138, in accordance with some embodiments.

In some embodiments, the contact etch stop layer 138 is made of a dielectric materials, such as silicon nitride, silicon oxide, silicon oxynitride, another suitable dielectric material, or a combination thereof. The dielectric material for the contact etch stop layers 138 may be conformally deposited over the semiconductor structure by performing chemical vapor deposition (CVD), ALD, other application methods, or a combination thereof.

The ILD layer 140 may include multilayers made of multiple dielectric materials, such as silicon oxide, silicon nitride, silicon oxynitride, phosphosilicate glass (PSG), borophosphosilicate glass (BPSG), or another applicable low-k dielectric material. The ILD layer 140 may be formed by chemical vapor deposition (CVD), physical vapor deposition, (PVD), atomic layer deposition (ALD), or another applicable process.

After the contact etch stop layer 138 and the ILD layer 140 are deposited, a planarization process such as CMP or an etch-back process may be performed until the gate electrode layers 120 of the first dummy gate structure 118a and the second dummy gate structure 118b are exposed, as shown in FIG. 3F-3 in accordance with some embodiments.

Afterwards, as shown in FIGS. 3G-1, 3G-2 and 3G-3, a dielectric wall structure 146 is formed between the two adjacent S/D structures 136, in accordance with some embodiments. In addition, the first dielectric wall structure 146 is formed between the first fin structure 104a and the second fin structure 104b. The first dielectric wall structure 146 is used to divide two adjacent merged S/D structures 136 to reduce the leakage. As a result, a portion of the merged S/D structures 136 is in direct contact with the first dielectric wall structure 146.

The first dielectric wall structure 146 includes a liner layer 142 and a filling layer 144 formed on the liner layer 142. The first dielectric wall structure 146 is formed by forming a trench (not shown) along the first direction (e.g. x-axis), and the trench is through the ILD layer 140, the CESL 138 (as shown in FIG. 3G-1), the gate spacer layer 126 and the dummy gate electrode layer 122. In addition, as shown in FIG. 3G-2, the trench is further through the dummy gate dielectric layer 120 and the isolation structure 116. Next, the liner layer 142 and the filling layer 144 are formed in the trench.

It should be noted that the bottom surface of the first dielectric wall structure 146 is lower than the bottom surface of the S/D structure 136. In some embodiments, there is a distance between the bottom surface of the first dielectric wall structure 146 and the bottom surface of the S/D structure 136. In addition, the bottom surface of the first dielectric wall structure 146 is lower than the bottommost first semiconductor layer 106. The bottom surface of the first dielectric wall structure 146 is lower than the top surface of the isolation structure 116. In other words, the top surface of the isolation structure 116 is higher than the bottom surface of the first dielectric wall structure 146.

In some embodiments, the liner layer 142 is made of silicon nitride. In some embodiments, the liner layer 142 is formed by chemical vapor deposition (CVD), physical vapor deposition, (PVD), atomic layer deposition (ALD), or another applicable process. The filling layer 144 may be a single layer or multiple layers. In some embodiments, the filling layer 144 is made of silicon oxide (SiOx), silicon nitride (SiN), silicon carbide (SiC), silicon oxynitride (SiON), silicon carbon nitride (SiCN), silicon oxide carbonitride (SiOCN), and/or a combination thereof. In some embodiments, the filling layer 144 is formed by chemical vapor deposition (CVD), physical vapor deposition, (PVD), atomic layer deposition (ALD), or another applicable process.

Next, as shown in FIGS. 3H-1, 3H-2 and 3H-3, the dummy gate electrode layer 122 is removed to form a trench 151, in accordance with some embodiments.

The dummy gate electrode layer 122 is removed by one or more etching processes. For example, when the dummy gate electrode layer 122 is polysilicon, a wet etchant such as a tetramethylammonium hydroxide (TMAH) solution may be used to selectively remove the dummy gate electrode layer 122.

Afterwards, as shown in FIGS. 31-1, 31-2 and 31-3, the dummy gate dielectric layer 120 is removed to expose the first fin structure 104a and the second fin structure 104b, in accordance with some embodiments.

In some embodiments, the dummy gate dielectric layer 120 is removed by using a plasma dry etching, a dry chemical etching, and/or a wet etching.

Next, as shown in FIGS. 3J-1, 3J-2 and 3J-3, the first semiconductor material layers 106 are removed to form nanostructures 108′ (or channel layers 108′) with the second semiconductor material layers 108, in accordance with some embodiments. As a result, gaps 153 are formed adjacent to the nanostructures 108′ (or channel layers 108′).

Afterwards, as shown in FIGS. 3K-1, 3K-2 and 3K-3, after the nanostructures 108′ are formed, the interfacial layer 154, the gate dielectric layer 156, and the gate electrode layer 158 are formed in the trench 151 and the gaps 153, in accordance with some embodiments. It should be noted that the gate dielectric layer 156 are formed on sidewall surfaces of the first dielectric wall structure 146 since the gate dielectric layer 156 is formed after the first dielectric wall structure 146 is formed.

After the interfacial layers 154, the gate dielectric layers 156, and the gate electrode material are formed, a planarization process such as CMP or an etch-back process may be performed. After the planarization process, the gate electrode layer 158 is divided into two portions by the first dielectric wall structure 146 to form a first gate structure 160a and a second gate structure 160b.

After the nanostructures 108′ are formed, the first gate structure 160a and the second gate structure 160b are formed wrapped around the nanostructures 108′. The first gate structure 160a and the second gate structure 160b wrap around the nanostructures 108′ to form gate-all-around transistor structures, in accordance with some embodiments. In some embodiments, the first gate structure 160a includes the interfacial layer 154, the gate dielectric layer 156, and the gate electrode layer 158. In some embodiments, the second gate structure 160b includes the interfacial layer 154, the gate dielectric layer 156, and the gate electrode layer 158.

In some embodiments, the interfacial layers 154 are oxide layers formed around the nanostructures 108′ and on the top of the base fin structure 105. In some embodiments, the interfacial layers 154 are formed by performing a thermal process.

In some embodiments, the gate dielectric layers 156 are formed over the interfacial layers 154, so that the nanostructures 108′ are surrounded (e.g. wrapped) by the gate dielectric layers 156. In addition, the gate dielectric layers 156 also cover the sidewalls of the gate spacer layers 126 and the inner spacer layers 134 in accordance with some embodiments. In some embodiments, the gate dielectric layers 156 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂-Al₂O₃) alloy, another suitable high-k dielectric material, or a combination thereof. In some embodiments, the gate dielectric layers 156 are formed using chemical vapor deposition (CVD), atomic layer deposition (ALD), another applicable method, or a combination thereof.

In some embodiments, the first gate structure 160a and the second gate structure 160b are formed on the gate dielectric layer 156. In some embodiments, the first gate structure 160a and the second gate structure 160b are made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof.

In some embodiments, the first gate structure 160a and the second gate structure 160b are formed using chemical vapor deposition (CVD), atomic layer deposition (ALD), electroplating, another applicable method, or a combination thereof. Other conductive layers, such as work function metal layers, may also be formed in the first gate structure 160a and the second gate structure 160b, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

Next, as shown in FIGS. 3L-1, 3L-2 and 3L-3, an etch stop layer 170 is formed over the gate structure 142, and a dielectric layer 172 is formed over the etch stop layer 170, in accordance with some embodiments.

In some embodiments, the etch stop layer 170 is made of a dielectric materials, such as silicon nitride, silicon oxide, silicon oxynitride, another suitable dielectric material, or a combination thereof. The dielectric material for the etch stop layers 170 may be conformally deposited over the semiconductor structure by performing chemical vapor deposition (CVD), ALD, other application methods, or a combination thereof.

The dielectric layer 172 may include multilayers made of multiple dielectric materials, such as silicon oxide, silicon nitride, silicon oxynitride, phosphosilicate glass (PSG), borophosphosilicate glass (BPSG), or another applicable low-k dielectric material. The dielectric layer 172 may be formed by chemical vapor deposition (CVD), physical vapor deposition, (PVD), atomic layer deposition (ALD), or another applicable process.

Next, a silicide layer 174 and an S/D contact structure 176 are formed over the S/D structure 136, in accordance with some embodiments. In some embodiments, the contact openings may be formed through the contact etch stop layer 138, the interlayer dielectric layer 140, the etch stop layer 170 and the dielectric layer 172 to expose the top surfaces of the S/D structures 136, and then the silicide layers 174 and the S/D contact structure 176 may be formed in the contact openings. The contact openings may be formed using a photolithography process and an etching process. In addition, some portions of the S/D structure 136 exposed by the contact openings may also be etched during the etching process.

The silicide layers 174 may be formed by forming a metal layer over the top surfaces of the S/D structure 136 and annealing the metal layer so the metal layer reacts with the S/D structure 136 to form the silicide layers 174. The unreacted metal layer may be removed after the silicide layers 174 are formed.

The S/D contact structure 176 may include a barrier layer and a conductive layer. In some other embodiments, the S/D contact structure 176 does not include a barrier layer. In some embodiments, the barrier layer is made of titanium (Ti), titanium nitride (TiN), tantalum (Ta), tantalum nitride (TaN), or another applicable material. In some embodiments, the barrier layer is formed by using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition process. In some embodiments, the conductive layer is made of tungsten (W), ruthenium (Ru), molybdenum (Mo), or the like. In some embodiments, the conductive layer is formed by performing a deposition process, such as chemical vapor deposition (CVD), physical vapor deposition, (PVD), atomic layer deposition (ALD), or another applicable process.

It should be noted that the merged S/D structures 136 are isolated or separated from the first dielectric wall structure 146, and any unwanted connection between the merged adjacent S/D structures 136 is prevented. Therefore, any unwanted leakage of the semiconductor structure 100a is reduced, and the performance of the semiconductor structures 100a is improved. In addition, the first dielectric wall structure 146 extends from the S/D region to the gate region, and it can be a barrier wall between two adjacent S/D structures 136 and can divide or cut the gate electrode layer 158 into two portions.

FIG. 3L′-1 illustrates a cross-sectional representation of a semiconductor structure 100b, in accordance with some embodiments. The semiconductor structure 100b of FIG. 3L′-1 includes elements that are similar to, or the same as, elements of the semiconductor structure 100a of FIG. 3L-1.

FIG. 3L′-1 is are similar to, or the same as, FIG. 3L-1, the difference between FIG. 3L′-1 and FIG. 3L is that the two adjacent S/D structure 136 are not merged.

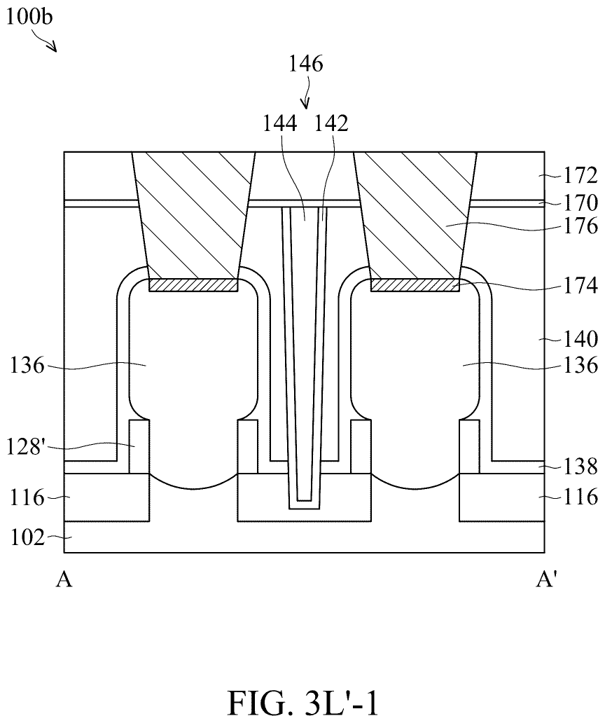

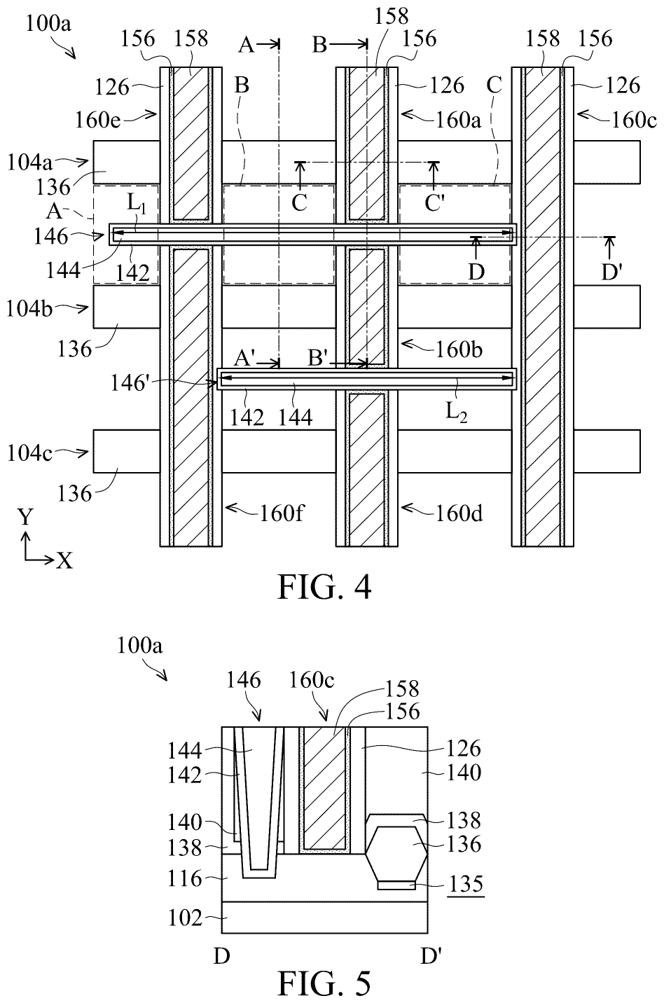

FIG. 4 shows a top-view representation of the semiconductor structure 100a after forming the first gate structure 160a and the second gate structure 160b, in accordance with some embodiments. Some elements are not shown for clarity.

FIG. 3L-1 illustrates the cross-sectional representation shown along line A-A′ in FIG. 4. FIG. 3L-2 illustrates the cross-sectional representation shown along line B-B′in FIG. 4, in accordance with some embodiments. FIG. 3L-3 illustrates the cross-sectional representation shown along line C-C′ in FIG. 4.

As shown in FIG. 4, the longitudinal axis of the first dielectric wall structure 146 is and the second dielectric wall structure 146′ are along first direction (e.g. x-axis). A third gate structure 160c is formed along the second direction (e.g. y-axis). A fifth gate structure 160e and a sixth gate structure 160f are formed along the second direction (e.g. y-axis).

The first dielectric wall structure 146 is formed between the merged S/D structures 136 in region A, the fifth gate structure 160e and the sixth gate structure 160f, and the merged S/D structures 136 in region B, the first gate structure 160a and the second gate structure 160b and the merged S/D structures 136 in region C. One end of the first dielectric wall structure 146 stops at the merged S/D structures 136, and the other end of the first dielectric wall structure 146 extends beyond the sidewall surface of the gate spacer layer 126 of the third gate structure 160c. In other words, the other end of the first dielectric wall structure 146 stops on the gate spacer layer 126 of the third gate structure 160c.

It should be noted that since the first dielectric wall structure 146 extends beyond the sidewall surface of the gate spacer layer 126 of the third gate structure 160c, the end of the first dielectric wall structure 146 extends beyond the outer sidewall surface of the merged S/D structure 136 in the region C when seen from a top-view. The end of the first dielectric wall structure 146 extends beyond the outer sidewall surface of the merged S/D structure 136 in the region C to make sure the merged S/D structure 136 can be completely divided.

A second dielectric wall structure 146′ is formed along the first direction (e.g. x-axis). The second dielectric wall structure 146′ is parallel to the first dielectric wall structure 146. The second dielectric wall structure 146′ is between the second gate structure 160b and a fourth gate structure 160d. One end of the second dielectric wall structure 146′ extends beyond the sidewall surface of the gate spacer layer 126 of the sixth gate structure 160f. The other end of the second dielectric wall structure 146′ extends beyond the sidewall surface of the gate spacer layer 126 of the third gate structure 160c. The other end of the second dielectric wall structure 146′ is in direct contact with the gate spacer layer 126 of the third gate structure 160c. The second length L2 of the second dielectric wall structure 146′ along the first direction (e.g. x-axis) is smaller than the first length L1 of the first dielectric wall structure 146.

As shown in FIG. 4, since the gate dielectric layer 156 is formed after the first dielectric wall structure 146 is formed, and the gate dielectric layer 156 is formed along the sidewall surface of the first dielectric wall structure 146 when seen from a top-view. The gate dielectric layer 156 has U-shaped structure. More specifically, the gate dielectric layer 156 is in direct contact with the liner layer 144 of the first dielectric wall structure 146. In some embodiments, the first dielectric wall structure 146 and the second dielectric wall structure 146′ both have a rectangular structure when seen from a top-view.

The first dielectric wall structure 146 is a continuous structure and extends from the S/D region to the gate region. The first dielectric wall structure 146 can be used as the barrier wall between two adjacent S/D structures 136 to reduce the leakage. Furthermore, the first dielectric wall structure 146 can also be used as the barrier layer between two adjacent gate structures 160a, 160b to divide the first gate structure 160a and the second gate structure 160b. By forming the first dielectric wall structure 146 between two adjacent S/D structures 136, any unwanted connection between two adjacent S/D structures 136 is prevented. Therefore, the leakage issue of the semiconductor structure 100a is reduced and the yield of the semiconductor structure 100a is increased. Therefore, the performance of the semiconductor structure 100a is improved.

FIG. 5 illustrates a cross-sectional representation of the semiconductor structure 100a shown along line D-D′ in FIG. 4, in accordance with some embodiments. Some elements are not shown for clarity.

As shown in FIG. 5, the first dielectric wall structure 146 is formed on the left side of the third gate structure 160c, and the S/D structure 136 is formed on the right side of the third gate structure 160c. A portion of the first dielectric wall structure 146 is in direct contact with the gate spacer layer 126 of the third gate structure 160c. In some embodiments, a void 135 is formed between the S/D structure 136 and the isolation structure 116.

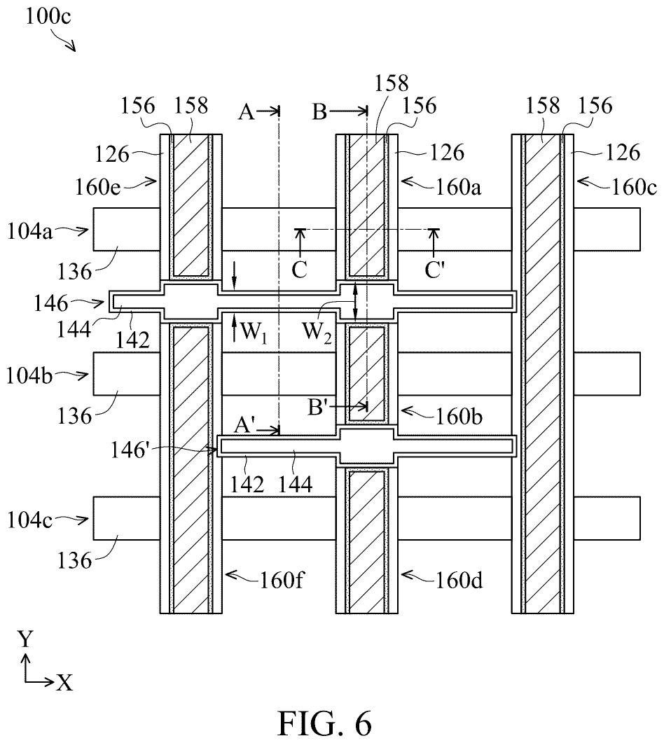

FIG. 6 shows a top-view representation of a semiconductor structure 100c, in accordance with some embodiments. FIG. 6 includes elements that are similar to, or the same as, elements of the semiconductor structure 100a of FIG. 4. As shown in FIG. 6, the first dielectric wall structure 146 has a cross-shaped structure when seen from a top-view. The first dielectric wall structure 146 does not have uniform width along the second direction (e.g. y-axis).

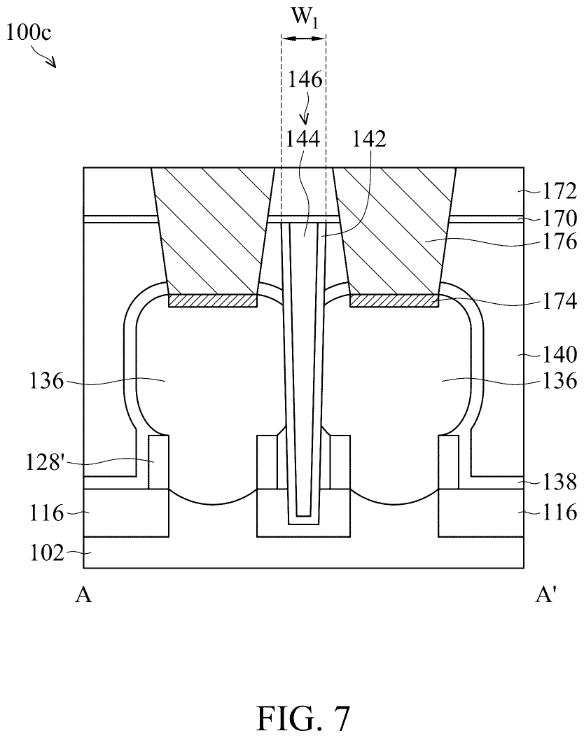

FIG. 7 illustrates a cross-sectional representation of the semiconductor structure 100c shown along line A-A′ in FIG. 6, in accordance with some embodiments. FIG. 8 illustrates a cross-sectional representation of the semiconductor structure 100c shown along line B-B′ in FIG. 6, in accordance with some embodiments.

As shown in FIGS. 6, 7 and 8, the first portion of the first dielectric wall structure 146 between two adjacent S/D structures 136 has a first width W₁ along the second direction. The second portion of the first dielectric wall structure 146 between the first gate structure 160a and the second gate structure 160b has a second width W₂ along the second direction. In some embodiments, the first width W₁ of the first portion of the first dielectric wall structure 146 is smaller than the second width W₂ of the second portion of the first dielectric wall structure 146. In some embodiments, the difference between the first width W₁ and the second width W₂ is in a range from about 2 nm to about 40 nm.

FIGS. 9A-1 to 9E-1 illustrate cross-sectional representations of various stages of manufacturing a semiconductor structure 100d shown along line A-A′ in FIG. 1E and in FIG. 2, in accordance with some embodiments. FIGS. 9A-2 to 9E-2 illustrate cross-sectional representations of various stages of manufacturing the semiconductor structure 100d shown along line B-B′ in FIG. 1E and in FIG. 2, in accordance with some embodiments. FIGS. 9A-3 to 9E-3 illustrate cross-sectional representations of various stages of manufacturing the semiconductor structure 100d shown along line C-C′ in FIG. 1E and in FIG. 2, in accordance with some embodiments.

The semiconductor structure 100d as shown in FIGS. 9A-1, 9A-2 and 9A-3 is similar to the semiconductor structure 100a as shown in FIGS. 3F-1, 3F-2 and 3F-3.

Next, as shown in FIGS. 9B-1, 9B-2 and 9B-3, the dummy gate electrode layer 122 is removed to form the trench 151, and then the dummy gate dielectric layer 120 is removed, in accordance with some embodiments. Next, the first semiconductor material layers 106 are removed to form nanostructures 108′ (or channel layers 108′). The gaps 153 are formed between two adjacent second semiconductor layers 108.

Afterwards, as shown in FIGS. 9C-1, 9C-2 and 9C-3, after the nanostructures 108′ are formed, the interfacial layer 154, the gate dielectric layer 156, and the gate electrode layer 158 are formed in the trench 151 and the gaps 153, in accordance with some embodiments.

Next, as shown in FIGS. 9D-1, 9D-2 and 9D-3, the first dielectric wall structure 146 is formed between two adjacent S/D structures 136, and divides or cuts the gate electrode layer 158 into two portions, in accordance with some embodiments. As a result, the first gate structure 160a is isolated from the second gate structure 160b by the first dielectric wall structure 146.

Afterwards, as shown in FIGS. 9E-1, 9E-2 and 9E-3, the etch stop layer 170 is formed over the gate structures 160a, 160b, and the dielectric layer 172 is formed over the etch stop layer 150, in accordance with some embodiments. Next, the silicide layer 174 and an S/D contact structure 176 are formed over the S/D structure 136. The S/D structure 136 is electrically connected to the S/D contact structure 176.

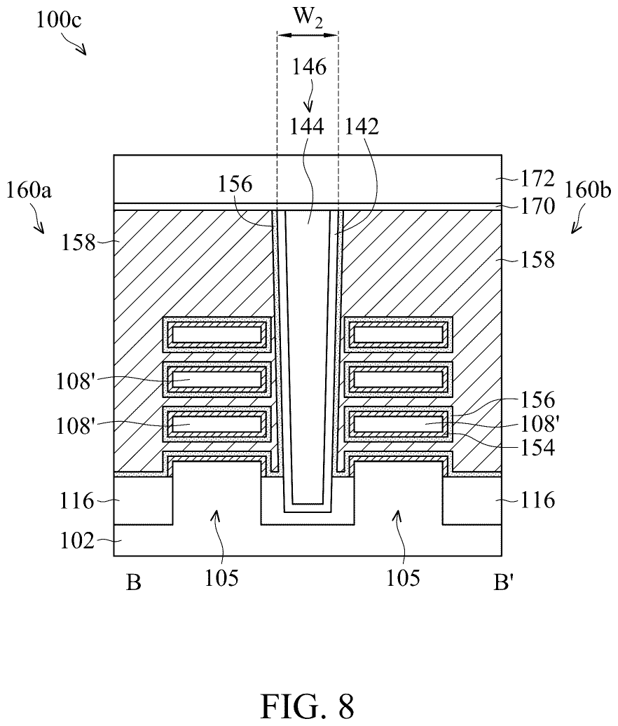

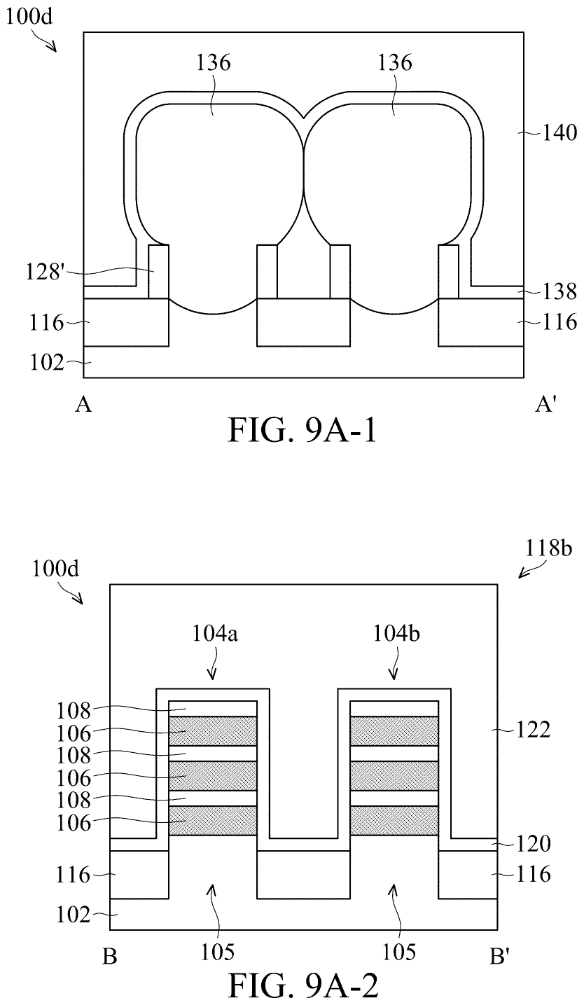

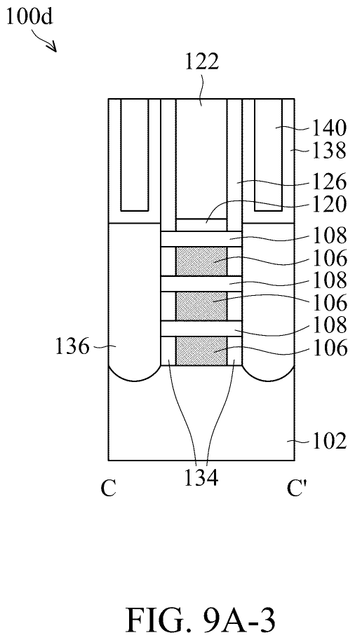

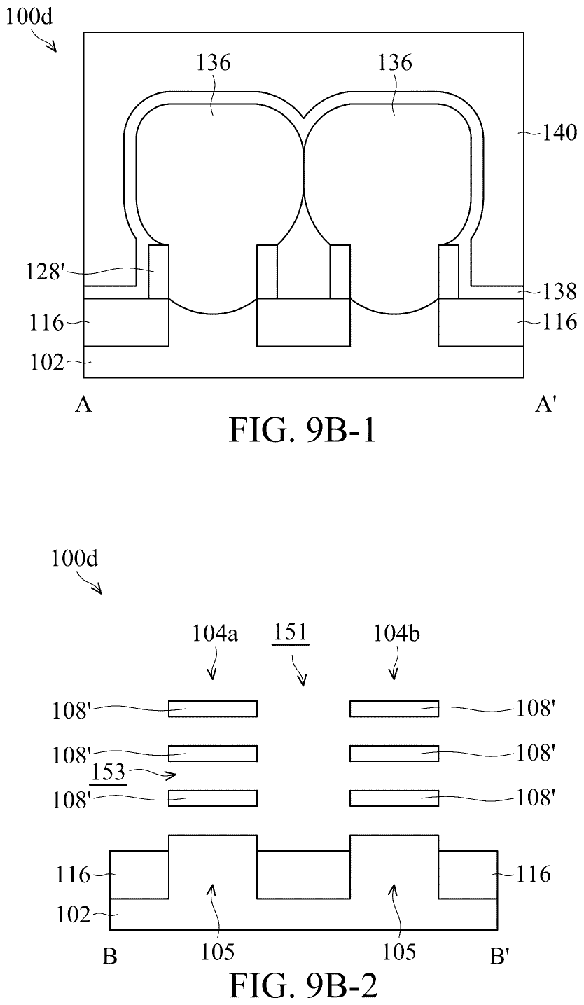

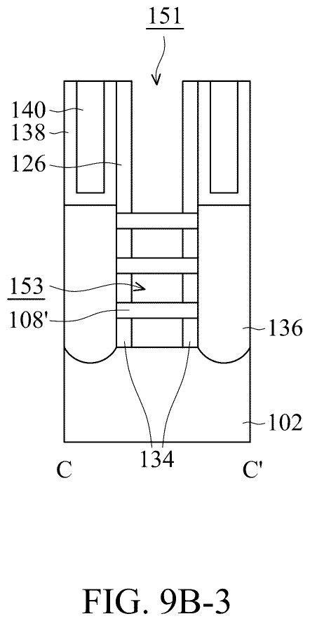

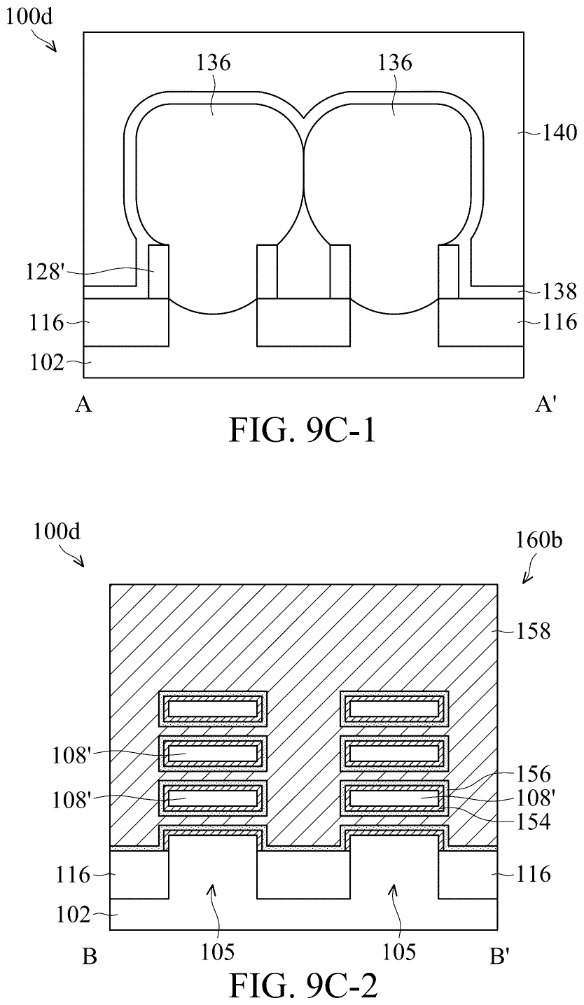

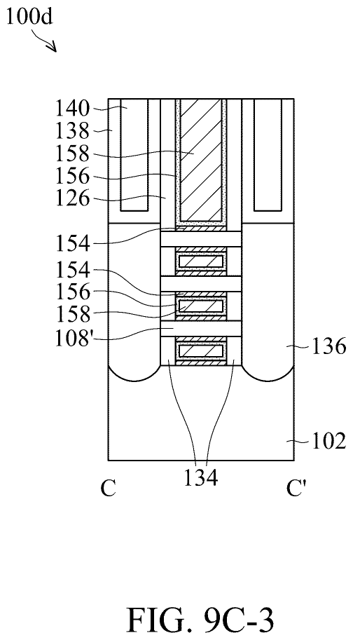

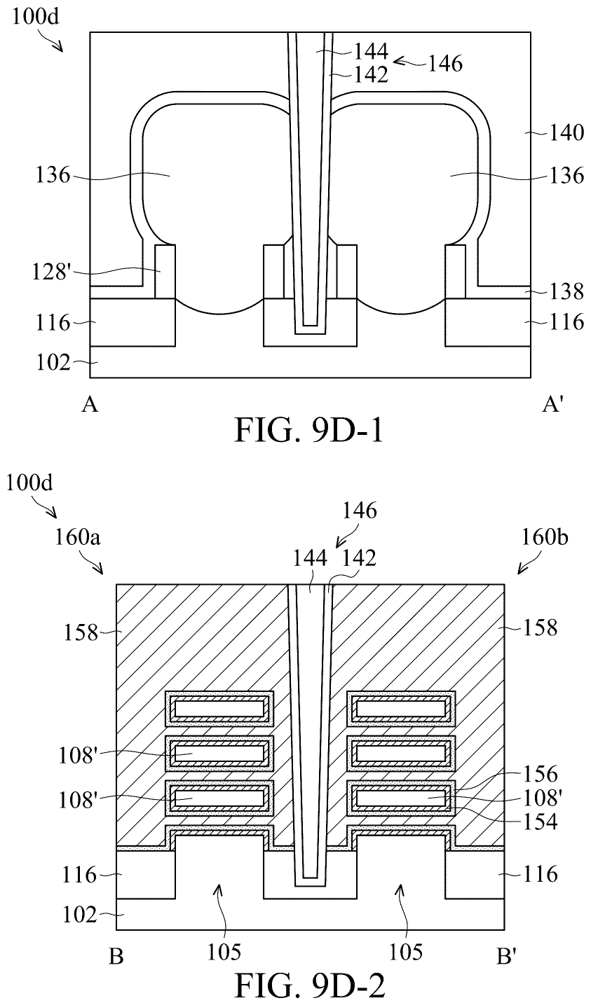

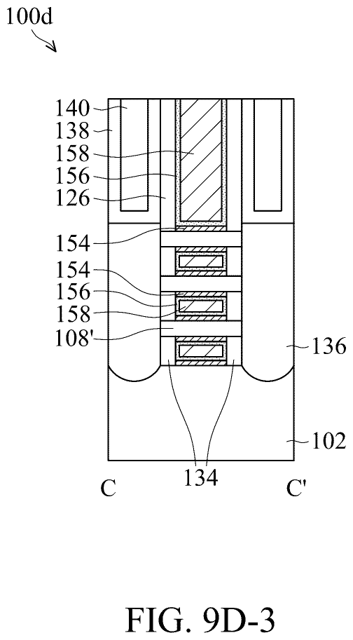

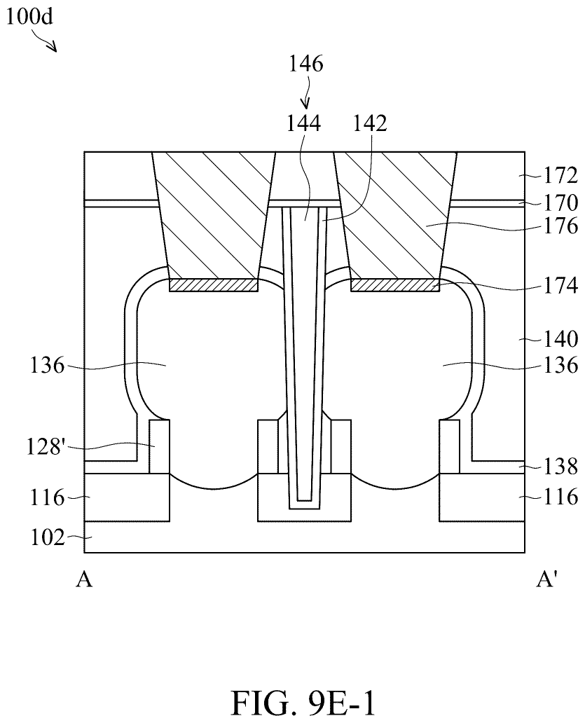

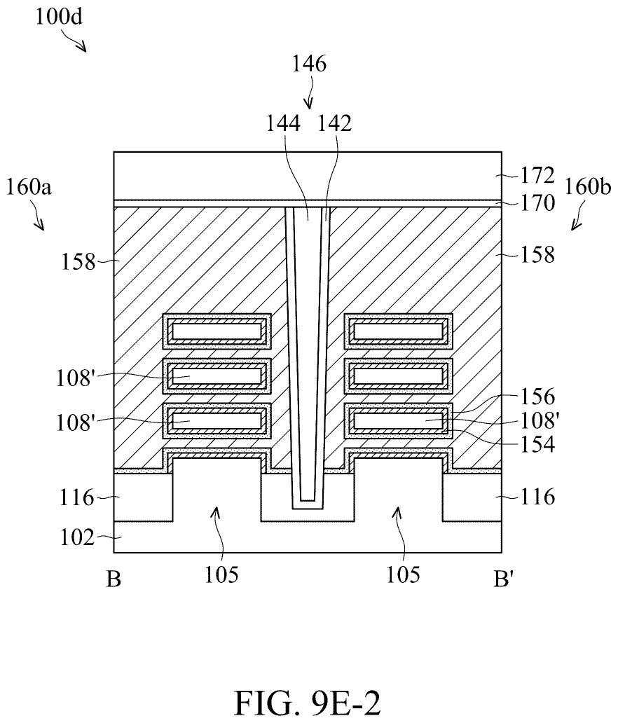

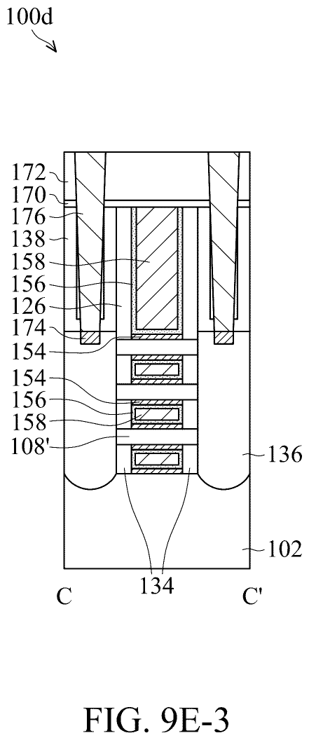

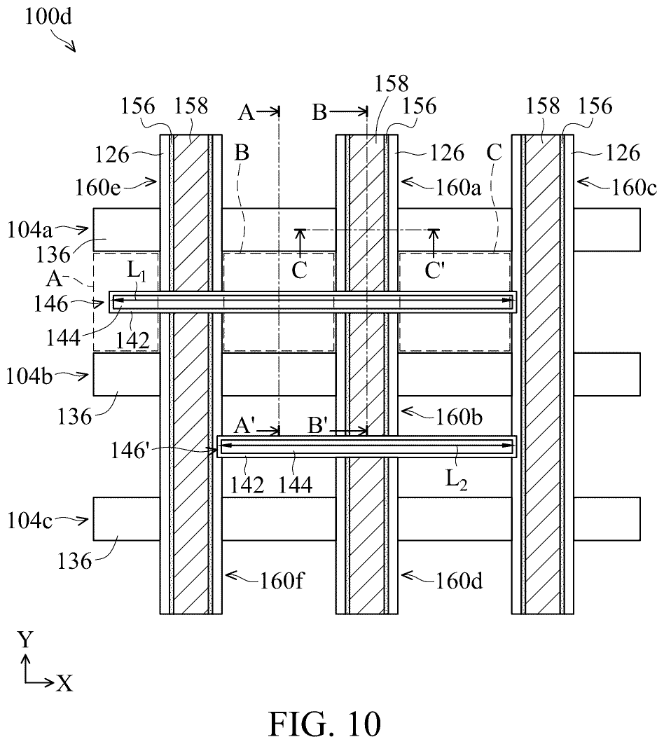

FIG. 10 shows a top-view representation of the semiconductor structure 100d after forming the first dielectric wall structure 146, in accordance with some embodiments. FIG. 9D-1 illustrates the cross-sectional representation shown along line A-A″ in FIG. 10. FIG. 9D-2 illustrates the cross-sectional representation shown along line B-B′ in FIG. 10, in accordance with some embodiments. FIG. 9D-3 illustrates the cross-sectional representation shown along line C-C′ in FIG. 10.

As shown in FIG. 10, the first dielectric wall structure 146 is formed along the second direction (e.g. y-axis). The second dielectric wall structure 146′ is also formed along the second direction (e.g. y-axis).

It should be noted, since the gate dielectric layer 156 is formed before the first dielectric wall structure 146 is formed, and the shape of the gate dielectric layer 156 shown in FIG. 10 is different from the shape of gate dielectric layer 156 (with U-shaped structure) shown in FIG. 4.

It should be noted that one end of the first dielectric wall structure 146 stops at the merged S/D structures 136, and the other end of the first dielectric wall structure 146 extends beyond the sidewall surface of the gate spacer layer 126 of the third gate structure 160c. In other words, the other end of the first dielectric wall structure 146 stops on the gate spacer layer 126 of the third gate structure 160c. The end of the first dielectric wall structure 146 extends beyond the outer sidewall surface of the merged S/D structure 136 in the region C when seen from a top-view. The end of the first dielectric wall structure 146 extends beyond the outer sidewall surface of the merged S/D structure 136 in the region C to make sure the merged S/D structure 136 can be completely divided.

FIG. 11 shows a top-view representation of a semiconductor structure 100e, in accordance with some embodiments. FIG. 11 includes elements that are similar to, or the same as, elements of the semiconductor structure 100d of FIG. 10.

As shown in FIG. 11, the end of the first dielectric wall structure 146 is aligned with the outer sidewall surface of the gate spacer layer 126 of the third gate structure 160c. In other words, the sidewall surface of the first dielectric wall structure 146 is in direct contact with the outer sidewall surface of the gate spacer layer 126 of the third gate structure 160c.

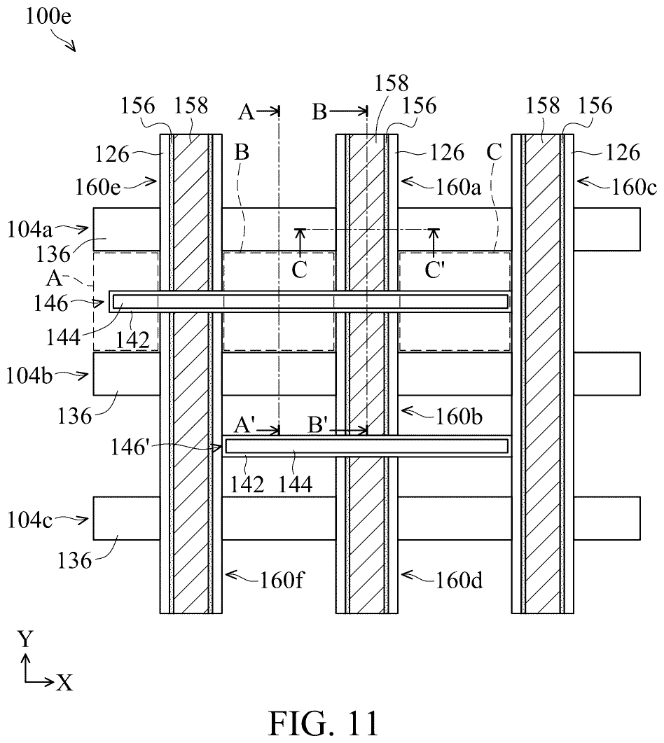

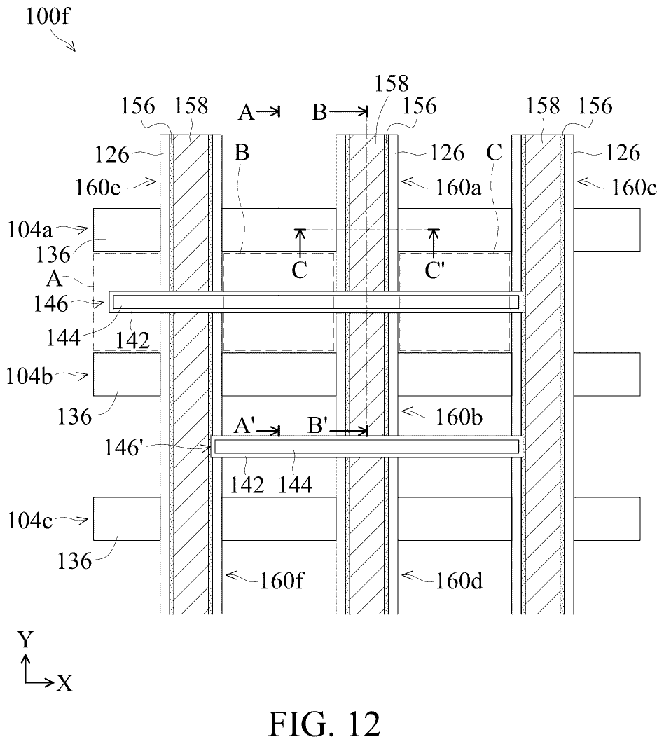

FIG. 12 shows a top-view representation of a semiconductor structure 100f, in accordance with some embodiments. FIG. 12 includes elements that are similar to, or the same as, elements of the semiconductor structure 100d of FIG. 10.

As shown in FIG. 12, the end of the first dielectric wall structure 146 is in direct contact with the gate dielectric layer 156 of the third gate structure 160c.

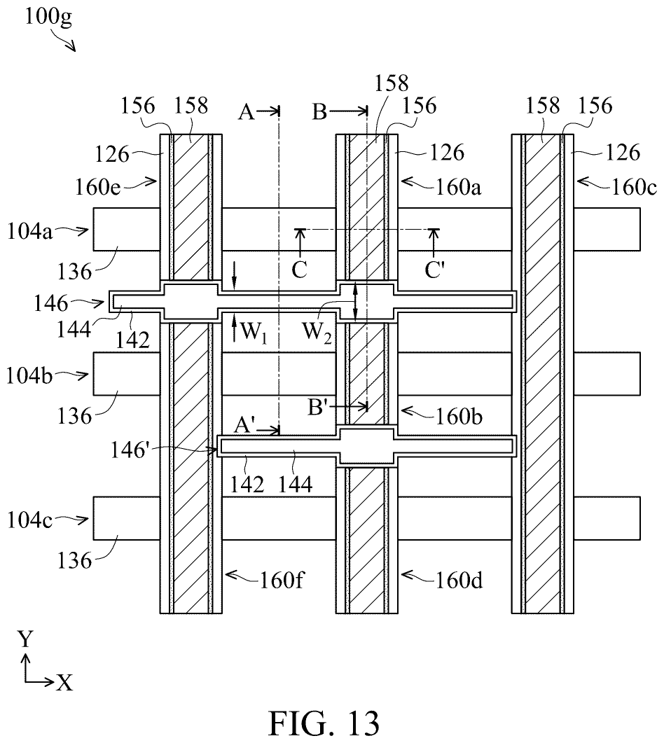

FIG. 13 shows a top-view representation of a semiconductor structure 100g, in accordance with some embodiments. FIG. 13 includes elements that are similar to, or the same as, elements of the semiconductor structure 100d of FIG. 10.

As shown in FIG. 13, the first dielectric wall structure 146 has a cross-shaped structure when seen from a top-view. The first dielectric wall structure 146 does not have uniform width along the second direction (e.g. y-axis).

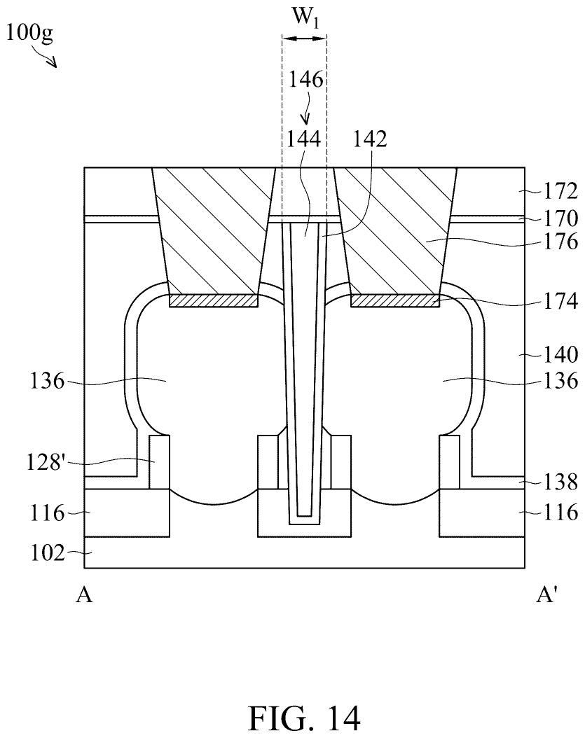

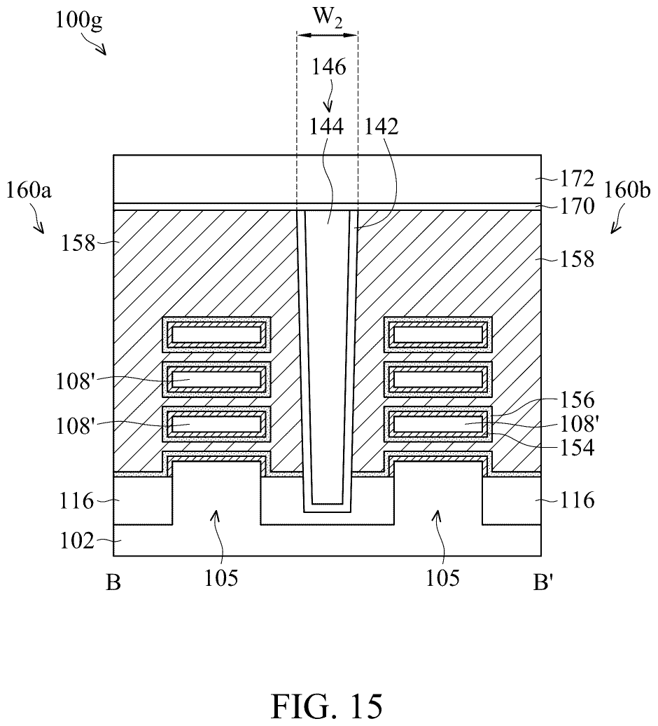

FIG. 14 illustrates a cross-sectional representation of the semiconductor structure 100e shown along line A-A′ in FIG. 13, in accordance with some embodiments. FIG. 15 illustrates a cross-sectional representation of the semiconductor structure 100e shown along line B-B′ in FIG. 13, in accordance with some embodiments.

As shown in FIGS. 13, 14 and 15, the first portion of the first dielectric wall structure 146 between two adjacent S/D structures 136 has a first width W₁ along the second direction. The second portion of the first dielectric wall structure 146 between the first gate structure 160a and the second gate structure 160b has a second width W₂ along the second direction. In some embodiments, the first width W₁ of the first portion of the first dielectric wall structure 146 is smaller than the second width W₂ of the second portion of the first dielectric wall structure 146. In some embodiments, the difference between the first width W₁ and the second width W₂ is in a range from about 2 nm to about 40 nm.

Since the two adjacent S/D structures 136 are isolated or separated from the first dielectric wall structure 146, or by the second dielectric wall structure 146′, any unwanted connection between the two adjacent S/D structures 136 is prevented. Therefore, the leakage of the semiconductor structures 100a-100g is reduced, and the performance and the yield of the semiconductor structures 100a-100g are improved.

It should be noted that same elements in FIGS. 1A to 15 may be designated by the same numerals and may include similar or the same materials and may be formed by similar or the same processes; therefore such redundant details are omitted in the interest of brevity. In addition, although FIGS. 1A to 15 are described in relation to the method, it will be appreciated that the structures disclosed in FIGS. 1A to 15 are not limited to the method but may stand alone as structures independent of the method. Similarly, although the methods shown in FIGS. 1A to 15 are not limited to the disclosed structures but may stand alone independent of the structures. Furthermore, examples of the nanostructures described above include nanowires, nanosheets, and other applicable nanostructures in accordance with some embodiments.

Also, while disclosed methods are illustrated and described below as a series of acts or events, it will be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming semiconductor structures may be provided. The semiconductor structure includes first nanostructures and second nanostructures along a first direction (e.g. x-axis). A first gate structure formed over the first nanostructures and the second nanostructures along the second direction (e.g. y-direction). A first S/D structure is formed over the first nanostructures, and a second S/D structure formed over the second nanostructures. A first gate spacer layer is formed on the sidewall surface of the first gate structure, and a second gate structure is formed parallel to the first gate structure. A second gate spacer layer is formed on the sidewall surface of the second gate structure. A first dielectric wall structure is formed along the first direction, and the first dielectric wall structure is between the first S/D structure and the second S/D structure. One end of the first dielectric wall structure extends beyond the sidewall surface of the second gate spacer layer. The first dielectric wall structure is configured to divide the merged S/D structure, and the end of the first dielectric wall structure extends beyond the outer sidewall surface of the merged S/D structure to make sure the merged S/D structure is completely divided. Thus, any unwanted connection between the two adjacent S/D structures can be prevented. Therefore, the leakage of the semiconductor structures is reduced, and the performances and the yield of the semiconductor structures are improved.

In some embodiments, a semiconductor structure is provided. The semiconductor structure includes first nanostructures formed over a substrate along a first direction, and second nanostructures formed over the substrate along the first direction. The semiconductor structure includes a first S/D structure formed over the first nanostructures, and a second S/D structure formed over the second nanostructures. The semiconductor structure includes a first gate structure formed over the first nanostructures and the second nanostructures along a second direction, and a first gate spacer layer formed on a sidewall surface of the first gate structure. The semiconductor structure includes a second gate structure formed parallel to the first gate structure, and a second gate spacer layer formed on a sidewall surface of the second gate structure. The semiconductor structure includes a first dielectric wall structure formed along the first direction. The first dielectric wall structure is between the first S/D structure and the second S/D structure, and an end of the first dielectric wall structure extends beyond a sidewall surface of the second gate spacer layer.

In some embodiments, a semiconductor structure is provided. The semiconductor structure includes first nanostructures formed over a substrate along a first direction, and second nanostructures parallel to the first nanostructures. The semiconductor structure includes a merged S/D structure formed on the first nanostructures and the second nanostructures, and a first gate structure formed over the first nanostructures and the second nanostructures along a second direction. The semiconductor structure includes a second gate structure formed parallel to the first gate structure. The semiconductor structure includes a first dielectric wall structure formed along the first direction. The first gate structure and the merged S/D structure are divided by the first dielectric wall structure, and an end of the first dielectric wall structure extends beyond an outer sidewall surface of the merged S/D structure.

In some embodiments, a method for forming a semiconductor structure is provided. The method includes forming a first fin structure and a second fin structure over a substrate, and the first fin structure includes first semiconductor material layers and second semiconductor material layers alternately stacked, and the second fin structure includes first semiconductor material layers and second semiconductor material layers alternately stacked. The method includes forming a first dummy gate structure over the first fin structure and the second fin structure, and removing a portion of the first fin structure to form a first S/D structure. The method includes removing a portion of the second fin structure to form a second S/D structure, and the first S/D structure connects with the second S/D structure to form a merged S/D structure. The method includes replacing the first dummy gate structure with a first gate structure, and forming a dielectric wall structure to divide the first gate structure and the merged S/D structure, An end of the dielectric wall structure extends beyond an outer sidewall surface of the merged S/D structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
first nanostructures formed over a substrate along a first direction;
second nanostructures formed over the substrate along the first direction;
a first S/D structure formed over the first nanostructures;
a second S/D structure formed over the second nanostructures;
a first gate structure formed over the first nanostructures and the second nanostructures along a second direction;
a first gate spacer layer formed on a sidewall surface of the first gate structure;
a second gate structure formed parallel to the first gate structure;
a second gate spacer layer formed on a sidewall surface of the second gate structure; and
a first dielectric wall structure formed along the first direction, wherein the first dielectric wall structure is between the first S/D structure and the second S/D structure, and an end of the first dielectric wall structure extends beyond a sidewall surface of the second gate spacer layer.

2. The semiconductor structure as claimed in claim 1, wherein the first dielectric wall structure is in direct contact with the first S/D structure and the second S/D structure.

3. The semiconductor structure as claimed in claim 1, wherein the end of the first dielectric wall structure is in direct contact with a gate dielectric layer of the second gate structure.

4. The semiconductor structure as claimed in claim 1, wherein a bottom surface of the first dielectric wall structure is lower than a bottom surface of the first S/D structure.

5. The semiconductor structure as claimed in claim 1, further comprising:
an isolation structure formed over the substrate, wherein a top surface of the isolation structure is higher than a bottom surface of the first dielectric wall structure.

6. The semiconductor structure as claimed in claim 1, wherein the first dielectric wall structure has a first portion and a second portion, the first portion of the first dielectric wall structure has a first width along the second direction, the second portion of the first dielectric wall structure has a second width along the second direction, and the first width is smaller than the second width.

7. The semiconductor structure as claimed in claim 6, wherein the first dielectric wall structure has a cross-shaped structure when seen from a top-view.

8. The semiconductor structure as claimed in claim 1, wherein the first S/D structure and the second S/D structure form a merged S/D structure.

9. The semiconductor structure as claimed in claim 1, further comprising:
a second dielectric wall structure formed adjacent to the first dielectric wall structure, wherein one end of the second dielectric wall structure is in direct contact with the second gate spacer layer.

10. A semiconductor structure, comprising:
first nanostructures formed over a substrate along a first direction;
second nanostructures parallel to the first nanostructures;
a merged S/D structure formed on the first nanostructures and the second nanostructures; and
a first gate structure formed over the first nanostructures and the second nanostructures along a second direction;
a second gate structure formed parallel to the first gate structure; and
a first dielectric wall structure formed along the first direction, wherein the first gate structure and the merged S/D structure are divided by the first dielectric wall structure, and an end of the first dielectric wall structure extends beyond an outer sidewall surface of the merged S/D structure.

11. The semiconductor structure as claimed in claim 10, wherein the first dielectric wall structure is in direct contact with the merged S/D structure.

12. The semiconductor structure as claimed in claim 10, further comprising:
a second gate structure formed parallel to the first gate structure, wherein the end of the first dielectric wall structure is in direct contact with a gate dielectric layer of the second gate structure.

13. The semiconductor structure as claimed in claim 10, further comprising:
a second gate spacer layer formed on a sidewall surface of the second gate structure, wherein the end of the first dielectric wall structure is in direct contact with the second gate spacer layer.

14. The semiconductor structure as claimed in claim 10, wherein the first dielectric wall structure has a first portion and a second portion, the first portion of the first dielectric wall structure has a first width along the second direction, the second portion of the first dielectric wall structure has a second width along the second direction, and the first width is smaller than the second width.

15. The semiconductor structure as claimed in claim 10, further comprising:
a second dielectric wall structure formed adjacent to the first dielectric wall structure, wherein a length of the second dielectric wall structure is smaller than a length of the first dielectric wall structure.

16. The semiconductor structure as claimed in claim 10, wherein the first gate structure comprises a gate dielectric layer, and the gate dielectric layer is in direct contact with a sidewall surface of the first dielectric wall structure.

17. A method for forming a semiconductor structure, comprising:
forming a first fin structure and a second fin structure over a substrate, wherein the first fin structure comprises first semiconductor material layers and second semiconductor material layers alternately stacked, and the second fin structure comprises first semiconductor material layers and second semiconductor material layers alternately stacked;
forming a first dummy gate structure over the first fin structure and the second fin structure;
removing a portion of the first fin structure to form a first S/D structure;
removing a portion of the second fin structure to form a second S/D structure, wherein the first S/D structure connects with the second S/D structure to form a merged S/D structure;
replacing the first dummy gate structure with a first gate structure; and
forming a dielectric wall structure to divide the first gate structure and the merged S/D structure, wherein an end of the dielectric wall structure extends beyond an outer sidewall surface of the merged S/D structure.

18. The method for forming the semiconductor structure as claimed in claim 17, further comprising:
forming a second dummy gate structure adjacent to the first dummy gate structure; and
forming a second gate spacer layer on a sidewall surface of the second dummy gate structure, wherein the end of the dielectric wall structure extends beyond a sidewall surface of the second gate spacer layer.

19. The method for forming the semiconductor structure as claimed in claim 18, further comprising:
replacing the second dummy gate structure with a second gate structure, wherein the end of the dielectric wall structure is in direct contact with a gate dielectric layer of the second gate structure.

20. The method for forming the semiconductor structure as claimed in claim 17, further comprising:
forming an isolation structure over the substrate, wherein a top surface of the isolation structure is higher than a bottom surface of the dielectric wall structure.
